(19) United States
(12) Patent Application Publication
(10) Pub. No.: US 2025/0169097 A1
(43) Pub. Date: May 22, 2025

(54) EPITAXIAL NITRIDE FERROELECTRONIC DEVICES

(71) Applicant: The Regents of the University of Michigan, Ann Arbor, MI (US)

(72) Inventors: Ding Wang, Ann Arbor, MI (US); Ping Wang, Ann Arbor, MI (US); Zetian Mi, Ann Arbor, MI (US)

(21) Appl. No.: 18/840,478

(22) PCT Filed: Feb. 23, 2023
(86) PCT No.: PCT/US2023/013727

§ 371 Date: Aug. 21, 2024

Related U.S. Application Data
(60) Provisional application No. 63/313,002, filed on Feb. 23, 2022.

(51) Int. Cl. H10D 30/47; H10B 51/30; H10D 30/69; H10D 48/38; H10D 62/824; H10D 62/85

(52) U.S. Cl. CPC H10D 30/475; H10B 51/30; H10D 30/701; H10D 48/381; H10D 62/824; H10D 62/8503

(57) ABSTRACT

A device includes a substrate, a heterostructure supported by the substrate, the heterostructure including a semiconductor layer supported by the substrate, and a ferroelectric III-nitride alloy layer supported by the semiconductor layer, the ferroelectric III-nitride alloy layer including a Group IIIB element, and first and second contacts in electrical communication with the ferroelectric III-nitride alloy layer and the semiconductor layer, respectively, such that a polarity of a poling voltage applied across the first and second contacts establishes a state of ferroelectric polarization of the ferroelectric III-nitride alloy layer

### CROSS-REFERENCE TO RELATED APPLICATION

This application claims the benefit of U.S. provisional application entitled “Epitaxial Nitride Ferroelectronic Devices,” filed Feb. 23, 2022, and assigned Ser. No. 63/313,002, the entire disclosure of which is hereby expressly incorporated by reference.

### STATEMENT REGARDING FEDERALLY SPONSORED RESEARCH OR DEVELOPMENT

This invention was made with government support under Contract No. N00014-19-1-2225 awarded by the U.S. Office of Naval Research. The government has certain rights in the invention.

### BACKGROUND OF THE DISCLOSURE

### Field of the Disclosure

The disclosure relates generally to ferroelectric Group III-nitride materials.

### Brief Description of Related Technology

The ability to control and tune electrical polarization of semiconductor materials has been investigated to enable the design and development of many types of devices, including, for instance, microelectronic memory devices for neuromorphic computing and artificial intelligence, reconfigurable filters for mobile communications, micro/nanoelectromechanical systems, and tunable two-dimensional electron/hole gas (2DEG/2DHG) heterojunctions. Wurtzite III-nitride semiconductors, e.g., AlN, GaN, InN, and their alloys, possess a strong polarization effect along the c-axis, including spontaneous and piezoelectric polarization. The polarization direction of conventional III-nitrides, however, cannot be electrically switched without causing dielectric breakdown.

Recent theoretical studies suggested that ferroelectric switching of III-nitride semiconductors could be potentially achieved through the incorporation of other noble metal elements and/or strain engineering. For example, the incorporation of Sc into AlN induces distortion of the wurtzite crystal structure, i.e., a reduction in the c/a ratio accompanied by an increase in the internal u parameter. The resulting tendency for transformation to a planar hexagonal structure leads to crystal structure destabilization and an enhanced piezoelectric response. Consequently, the electric field for ferroelectric polarization switching can be potentially reduced below its dielectric breakdown limit of wurtzite ScₓAl₁₋ₓN.

The synthesis and characterization of ScₓAl₁₋ₓN has been studied. Some studies on ScₓAl₁₋ₓN have largely focused on sputter deposition, and the ferroelectric switching of the resulting materials has been investigated. However, controlled synthesis of ScₓAl₁₋ₓN using molecular beam epitaxy (MBE) or metal-organic chemical vapor deposition (MOCVD) is also of interest. The epitaxial growth provides significantly improved material quality and enables seamless integration with III-N device technology. Pure wurtzite phase ScₓAl₁₋ₓN with Sc content up to 0.4 has been achieved using MBE. Further studies have confirmed that the energy bandgap decreases linearly with increasing Sc composition, in good agreement with theory. Other studies revealed that ScₓAl₁₋ₓN is optically active but is dominated by oxygen-defect related emission. To date, however, there has been no report on ferroelectric switching in ScₓAl₁₋ₓN grown by MBE or MOCVD.

### SUMMARY OF THE DISCLOSURE

In accordance with one aspect of the disclosure, a device includes a substrate, a heterostructure supported by the substrate, the heterostructure including a semiconductor layer supported by the substrate, and a ferroelectric III-nitride alloy layer supported by the semiconductor layer, the ferroelectric III-nitride alloy layer including a Group IIIB element, and first and second contacts in electrical communication with the ferroelectric III-nitride alloy layer and the semiconductor layer, respectively, such that a polarity of a poling voltage applied across the first and second contacts establishes a state of ferroelectric polarization of the ferroelectric III-nitride alloy layer.

In accordance with another aspect of the disclosure, a device includes a substrate, and a heterostructure supported by the substrate. The heterostructure includes a semiconductor layer supported by the substrate, and a ferroelectric III-nitride alloy layer supported by the semiconductor layer, the ferroelectric III-nitride alloy layer comprising a Group IIIB element. The semiconductor layer is doped to configure the semiconductor layer as an electrode layer having a charge carrier concentration to support resistive switching of a polarization state of the ferroelectric III-nitride alloy layer

In accordance with another aspect of the disclosure, a memory device includes a substrate, a heterostructure supported by the substrate, the heterostructure including a semiconductor layer supported by the substrate, and a ferroelectric III-nitride alloy layer supported by the semiconductor layer, the ferroelectric III-nitride alloy layer including a Group IIIB element, and a control circuit in electrical communication with the ferroelectric III-nitride alloy layer and the semiconductor layer, respectively, to apply a poling voltage and a read voltage across the ferroelectric III-nitride alloy layer and the semiconductor layer. A polarity of the poling voltage establishes a state of ferroelectric polarization of the ferroelectric III-nitride alloy layer, respectively. The read voltage is at a voltage level to generate a current through the heterostructure, the current having a level indicative of the state of ferroelectric polarization.

In accordance with yet another aspect of the disclosure, a method of operating a memory device includes applying a poling voltage across a heterostructure of the memory device to establish a polarization state of a ferroelectric III-nitride layer of the heterostructure, the ferroelectric III-nitride layer being supported by a semiconductor layer of the heterostructure, the ferroelectric III-nitride alloy layer including a Group IIIB element, applying a read voltage across the heterostructure, and determining a level of current flowing through the heterostructure in response to the read voltage for readout of the polarization state.

In connection with any one of the aforementioned aspects, the devices and/or methods described herein may alternatively or additionally include or involve any combination of one or more of the following aspects or features. The ferroelectric III-nitride alloy layer resides either in a first polarization state or a second polarization state. In the first polarization state, current through the heterostructure is at a first level in response to a read voltage applied across the first and second contacts. In the second polarization state, the current is at a second level in response to the read voltage. The first level is higher than the second level. The ferroelectric III-nitride alloy layer is in contact with the semiconductor layer to establish a heterointerface. The ferroelectric III-nitride alloy layer and the semiconductor layer are lattice matched. The ferroelectric III-nitride alloy layer is monocrystalline. The ferroelectric III-nitride alloy layer has a wurtzite structure. The semiconductor layer is doped to configure the semiconductor layer as an electrode layer having a charge carrier concentration to support resistive switching of a polarization state of the ferroelectric III-nitride alloy layer. The semiconductor layer includes Si-doped GaN. The semiconductor layer is in contact with the substrate. The ferroelectric III-nitride alloy layer includes ScAlN. The ferroelectric III-nitride alloy layer has a scandium content of about 18%. The ferroelectric III-nitride alloy layer is in contact with the semiconductor layer to establish a heterointerface. The ferroelectric III-nitride alloy layer and the semiconductor layer are lattice matched. The ferroelectric III-nitride alloy layer is a monocrystalline wurtzite structure. The semiconductor layer is Si-doped. The ferroelectric III-nitride alloy layer includes ScAlN. Applying the poling voltage includes selecting a level of the poling voltage to modulate a conductance of the polarization state. Applying the poling voltage includes selecting a level of the poling voltage based on an operating temperature. Applying the read voltage includes selecting a level of the read voltage based on the operating temperature. Applying the read voltage is implemented without implementation of a cooling procedure.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts an atomic force microscope (AFM) image of an epitaxially grown ScₓAl₁₋ₓN layer that exhibits ferroelectric characteristics in accordance with one example, along with a graphical plot of polarization-electric field (P-E) loops for ferroelectric layer examples having a range of scandium contents.

FIG. 2 depicts a graphical plot of current density as a function of electric field for a number of epitaxially grown ScₓAl₁₋ₓN layers in accordance with several examples, along with a graphical plots of the coercive field, breakdown field, and remnant polarization for varying levels of scandium content in epitaxially grown ScₓAl₁₋ₓN layers in accordance with several examples.

FIG. 3 depicts a graphical plot of polarization after positive and negative poling for an epitaxially grown ScₓAl₁₋ₓN layer in accordance with one example, as well as graphical plots of transient current and voltage profiles during positive-up and negative-down (PUND) measurements of an epitaxially grown ScₓAl₁₋ₓN layer in accordance with one example.

FIG. 4 depicts a graphical plot of remnant polarization during endurance testing of an epitaxially grown ScₓAl₁₋ₓN layer in accordance with one example, as well as a graphical plot of current density as a function of electric field for an epitaxially grown ScₓAl₁₋ₓN layer after a varying number of switching cycles in accordance with one example.

FIG. 5 is a graphical plot of the leakage current as a function of applied voltage for an epitaxially grown ScₓAl₁₋ₓN layer in accordance with one example.

FIG. 6 is a flow diagram of a method of fabricating a heterostructure having an epitaxially grown ferroelectric wurtzite structure in accordance with one example.

FIGS. 7A and 7B depict cross-sectional, schematic views of ferroelectric field effect transistor (FeFET) memory cells with a single-crystal, or monocrystalline, layer of an alloy of a III-nitride material (e.g., ScₓAl₁₋ₓN) between a gate electrode and a source-drain conduction region to provide a reversible electrical state in accordance with two examples.

FIG. 8 is a cross-sectional, schematic view of a ferroelectric-transistor random-access memory cell with a metal-ScₓAl₁₋ₓN-metal capacitor and a silicon or GaN based write-read transistor in accordance with one example.

FIGS. 9A and 9B are cross-sectional, schematic views of ferroelectric tunnel junction (FTJ) memory devices with a monocrystalline layer of an alloy of a III-nitride material (e.g., ScₓAl₁₋ₓN) in accordance with two examples.

FIGS. 10A and 10B are cross-sectional, schematic views of metal-polar and N-polar ferroelectric high electron mobility transistor (Fe-HEMT) devices, respectively, each having a monocrystalline layer of an alloy of a III-nitride material (e.g., ScₓAl₁₋ₓN) in accordance with two examples.

FIGS. 11A and 11B are cross-sectional, schematic views of a reconfigurable Fe-HEMT device having a monocrystalline layer of an alloy of a III-nitride material (e.g., ScₓAl₁₋ₓN) in accordance with one example, in which the polarization direction, indicated by green arrows, of a ferroelectric layer under a gate can be reconfigured by applying an electric field beyond the coercive field.

FIG. 12 is a cross-sectional, schematic view of a ferroelectric photovoltaic device with a monocrystalline layer of an alloy of a III-nitride material (e.g., ScₓAl₁₋ₓN) as a photon absorption layer in accordance with one example.

FIGS. 13A and 13B are cross-sectional, schematic views of ferroelectric photovoltaic devices, each having a monocrystalline layer of an alloy of a III-nitride material (e.g., ScₓAl₁₋ₓN) to provide one or more ferroelectric regions, and further having a monocrystalline layer of a III-nitride material as a photon absorption layer in accordance with two examples.

FIG. 14 is a cross-sectional, schematic view of a lateral homojunction device with a monocrystalline layer of an alloy of a III-nitride material (e.g., ScₓAl₁₋ₓN) to provide one or more ferroelectric regions in accordance with one example.

FIG. 15 depicts a schematic view of an epitaxial ScAlN/GaN heterostructure in accordance with one example, along with graphical plots of an XRD 2θ-ω scan, P-V and I-V loops, polarization loops, and amplitude and phases patterns for the example.

FIG. 16 are graphical plots of resistive switching behavior in a ScAlN/GaN heterostructure memory in accordance with one example, including graphical plots of I-V hysteretic loops, reading of ON/OFF current levels, retention time, and bipolar switching stability.

FIG. 17 are graphical plots of conductivity and polarization change measurements for a ScAlN/GaN heterostructure memory in accordance with one example, including graphical plots of current levels to show a conductivity hysteresis loop and pulse-width dependencies.

FIG. 18 depicts schematic views of energy band diagrams of a ScAlN/GaN heterostructure memory in accordance with one example, along with graphical plots of current levels and ON/OFF ratio as a function of charge carrier concentration.

FIG. 19 are graphical plots of P-V loop, ON/OFF current levels, and ON/OFF ratio measurements during high temperature operation.

FIG. 20 is a schematic view of a memory device having a heterostructure with a ferroelectric III-nitride alloy layer in accordance with one example.

FIG. 21 is a flow diagram of a method of operating a memory device having a heterostructure with a ferroelectric III-nitride alloy layer in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Methods for growth of epitaxial (e.g., fully epitaxial) ferroelectric alloys of III-nitride materials are described. The disclosed methods are configured to incorporate scandium (Sc) or other group IIIB elements into the wurtzite crystal structure of the III-nitride material. Molecular beam epitaxy (MBE), metal-organic chemical vapor deposition (MOCVD), hydride vapor phase epitaxy (HVPE), pulsed laser deposition (PLD), and other non-sputtered epitaxial growth procedures may be used to realize the ferroelectric III-nitride alloy layers. The disclosed methods may or may not include implementation of a post-growth annealing procedure. Devices and structures including such materials are also described. For instance, various heterostructures and ferroelectronic devices with one or more ferroelectric III-nitride alloy layers are described.

The disclosed devices and structures exhibit ferroelectric switching in one or more single-crystal, or monocrystalline, layers of an alloy of a III-nitride material, e.g., in ScₓAl₁₋ₓN films grown by molecular beam epitaxy (MBE). In some cases, the layers are grown on GaN templates or other III-nitride semiconductor layers. Still other types of semiconductor layers may be used. The ferroelectric properties of several examples of the ScₓAl₁₋ₓN films with varying Sc contents (e.g., with the Sc content, x, falling in a range from about 0.14 to about 0.36) are presented via polarization and current density over electric field (P-E and J-E, respectively) measurements. The polarization retention time and fatigue behavior of the examples are also presented. Ferroelectricity is exhibited in all of the examples of ScₓAl₁₋ₓN films. A coercive field of about 4.2 MV/cm was measured for Sc_{0.20}Al_{0.80}N at 10 KHz with a remnant polarization of about 135 μC/cm². Further testing revealed no obvious fatigue behavior after up to 3×10⁵ switching cycles. The disclosed methods and devices show the feasibility to control the electrical polarization of III-V semiconductors grown by MBE and other non-sputtered epitaxial growth procedures (e.g., MOCVD, HVPE, and PLD). The use of epitaxial growth procedures enables thickness scaling (e.g., into the nanometer regime). Epitaxial growth may be useful in fabricating a broad range of applications in electronic, photonic, optoelectronic, and ferroelectric devices.

In some examples, ScₓAl₁₋ₓN films were grown using a Veeco GENXpolar MBE system equipped with a radio-frequency (RF) plasma source. In these examples, a Si-doped GaN layer was first grown on GaN/sapphire template, which may be used as a bottom contact layer. Subsequently, a ScₓAl₁₋ₓN layer was grown. The layer may have a thickness of about 100 nanometers (nm), but the thickness may vary. The Sc content may be varied by tuning the Sc/Al flux ratio, which may be further confirmed by energy dispersive x-ray spectroscopy (EDS). Electrical properties of these examples were analyzed by a Radiant Precision Multiferroic II Ferroelectric Test System. Ferroelectric characterization of these examples was performed on parallel plate capacitors with 100-nm-thick Pt circular top electrodes structured by lift-off and an indium solder dot placed on the n-GaN as the bottom electrode. The diameters of the top electrodes were varied in a range of 20-50 μm. P-E and J-E hysteresis loops of these examples were measured with a triangular voltage. Standard positive-up and negative-down (PUND) measurements with a pulse width of 10 μs, and an inter-pulse delay of 1 ms, were used to detect the ferroelectricity loss in fatigue testing of the examples.

Although described in connection with examples of epitaxially grown ScₓAl₁₋ₓN layers, the disclosed methods and devices may be applied to a wide variety of III-nitride alloys. The disclosed methods and devices may thus include or involve the incorporation of scandium into other III-nitride wurtzite structures. For instance, the disclosed methods and devices may include or involve one or more epitaxially grown ScₓAl_{y}Ga_{1-x-y}N layers, ScₓGa₁₋ₓN layers, or ScₓIn₁₋ₓN layers. The configuration, construction, fabrication, and other characteristics of the heterostructures may also vary from the examples described. For instance, the heterostructures may include any number of epitaxially grown layers of ferroelectric and non-ferroelectric nature. The disclosed methods and devices are not limited to III-nitride alloys including scandium. For instance, the III-nitride alloys may include additional or alternative group IIIB elements, such as yttrium (Y) and lanthanum (La).

Although described in connection with examples having the III-nitride alloy layer adjacent to (e.g., epitaxially grown on) III-nitride semiconductor layers, the disclosed methods and devices are not limited to heterostructures including III-nitride semiconductor layers as a template, base, or other component. For instance, a number of examples are described in which the III-nitride alloy layer is grown on or otherwise supported by a metal layer, such as an aluminum layer. Additional or alternative other types of materials may also be used in the heterostructures, including, for instance, other semiconductor materials.

Although the disclosed methods are described in connection with MBE growth procedures, additional or alternative non-sputtered epitaxial growth procedures may be used. For instance, metal-organic chemical vapor deposition (MOCVD), hydride vapor phase epitaxy (HVPE), atomic layer deposition (ALD), and atomic layer epitaxy (ALE) growth procedures may be used. Still other procedures may be used, including, for instance, pulsed laser deposition procedures.

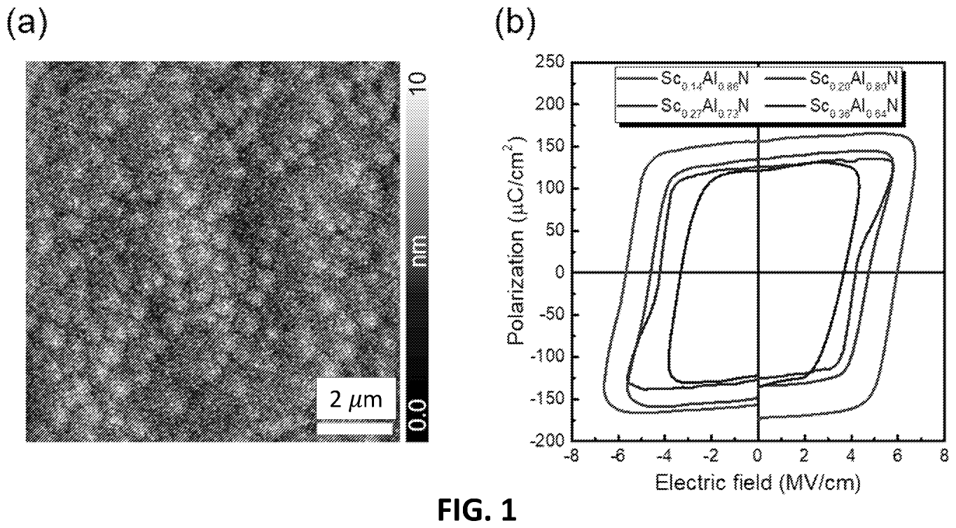

Part A of FIG. 1 depicts 10×10 μm² atomic force microscope (AFM) image of an example of a Sc_{0.20}Al_{0.80}N film grown in accordance with one example of the disclosed methods. The corresponding root-mean-square (RMS) roughness acquired from a 10×10 μm² scan area is about 1.1 nm. Other examples described herein exhibit similar surface morphology.

Part B of FIG. 1 depicts polarization-electric field (P-E) loops exhibited by the example. The P-E loops were measured at 40 KHz for ferroelectric ScₓAl₁₋ₓN with varying Sc contents. In these examples, the Sc content, x, varied from about 0.14 to about 0.36. Further details regarding the example are provided below.

The disclosed methods were used to grow a number of wurtzite-phase ScₓAl₁₋ₓN/GaN heterostructures. The ScₓAl₁₋ₓN layer of the heterostructures exhibited ferroelectric switching behavior. The Sc content, x, varied in the examples from about 0.14 to about 0.36. The Sc content may fall outside this range in other examples.

As described herein, the growth conditions (e.g., the growth temperature) are controlled to reduce (e.g., minimize) the formation of leakage current paths. The reduction of leakage current paths is useful for establishing the ferroelectricity of the layers.

The P-E loops shown in Part B of FIG. 1 were collected with a triangular voltage input with a frequency of 40 KHz. All of the ScₓAl₁₋ₓN films exhibited a clear hysteresis loop attributable to ferroelectricity, indicating a distinct ferroelectric polarization inversion across the entire Sc content range referenced above. The near-ideal box-like shape of each of the P-E loops indicates uniform incorporation of Sc and high crystal quality. Because the wurtzite structure possesses strong spontaneous polarization only along the c-axis, the domain rotation is configured for 180°, which enhances the coercive field significantly compared with other ferroelectric materials, such as PZT and In₂Se₃. The non-closed P-E loops and the indistinct polarization saturation for some of the examples can be attributed to the non-negligible leakage currents at very high electric fields. No leakage current compensation was applied to the data presented herein.

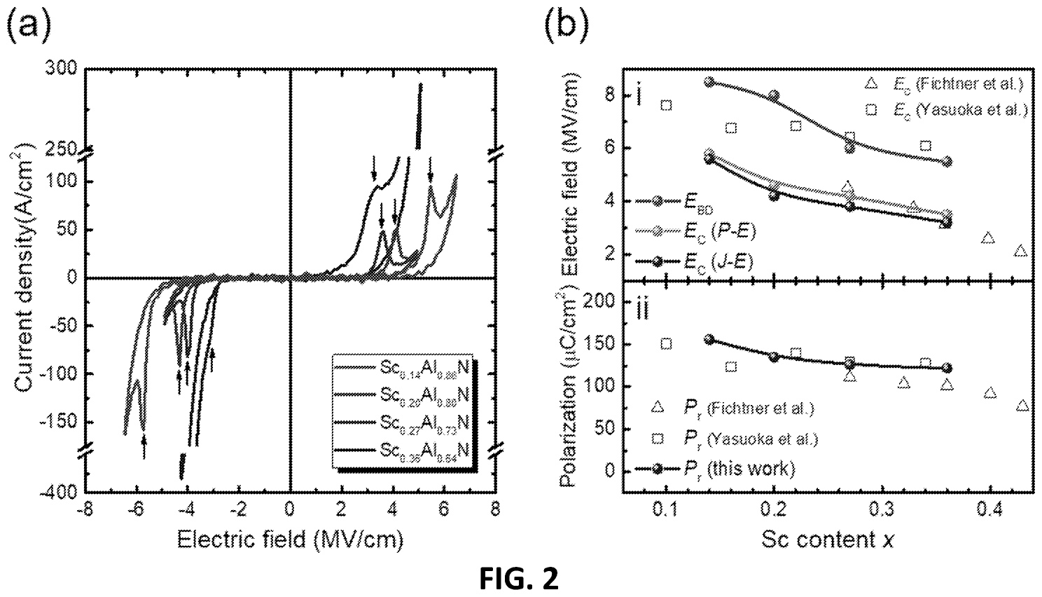

Part A of FIG. 2 depicts the corresponding J-E loops measured with the same triangular voltage input with a frequency of 10 KHz. The ferroelectricity of each of the ScₓAl₁₋ₓN film examples is unambiguously supported by instances of the switching current. Each instance is indicated by a respective black arrow in the graphical plot. The increase of current density when applying a large electric field above the level of the coercive field E_{c}, especially for Sc_{0.14}Al_{0.86}N and Sc_{0.36}Al_{0.64}N, indicates a large contribution from the leakage current. Nevertheless, current bumps due to electric dipole switching are still shown in the graphical plot. In this set of examples, the Sc_{0.36}Al_{0.64}N film exhibits the largest leakage current. This is mainly due to the degeneration of material quality and reduction of band gap with increasing Sc incorporation. Defect formations, such as high densities of threading dislocations, stacking faults, and point defects can act as leakage paths. Notwithstanding such leakage paths, layers of ScₓAl₁₋ₓN with lower (e.g., x less than or equal to about 0.10) and higher Sc content (e.g., x greater than or equal to 0.40) may also exhibit ferroelectric switching behavior.

Part B(i) of FIG. 2 depicts mean coercive fields levels for examples over a range of Sc content levels. The mean coercive field [E_{c}=(E⁺_{c}−E⁻_{c})/2] of ScₓAl₁₋ₓN films may be deduced from the P-E and J-E loops shown in Part B of FIG. 1 and Part A of FIG. 2. The E_{c} values reported by Fichtner et al. (measured at 711 Hz) 15 and Yasuoka et al. (measured at 100 kHz) are also plotted in Part B(i) of FIG. 2 for comparison. It has been experimentally demonstrated that the distortion of the robust wurtzite structure with increasing Sc content, i.e., shift of the internal u parameter towards the value for hexagonal structure (u=½), facilities polarization switching. Therefore, the nearly linear reduction of E_{c}, from about 5.7 MV/cm (Sc_{0.14}Al_{0.86}N) to about 3.4 MV/cm (Sc_{0.36}Al_{0.64}N), is believed to arise from the gradual lowering of the polarization switching barrier with increasing Sc content. It is also noticed that the E_{c} estimated from J-E loops is slightly lower than that acquired from the P-E loops. This is due to the different frequencies used for the P-E (40 KHz) and J-E (10 kHz) measurements. Normally, a relatively large electric field is used for polarization switching when applying a short pulse, that is, employing a high measurement frequency results in an increase of E_{c}. Considering the effect of measurement frequency, the E_{c} values for these examples of MBE grown ScₓAl₁₋ₓN films agree well with previous reports on ScₓAl₁₋ₓN formed by sputter deposition.

Part B(i) also depicts the average breakdown fields EBD of the ScₓAl₁₋ₓN examples acquired from five electrodes. The breakdown field levels are found to be around 2-3 MV/cm higher than the coercive field for each Sc content level, thereby enabling the polarization switching before dielectric breakdown occurs. This corresponds to a figure of merit ratio (EBD/E_{c}) up to about 1.9, which is better than that exhibited by ScₓAl₁₋ₓN films formed via sputter deposition.

Part B(ii) of FIG. 2 depicts the remnant polarization Pᵣ obtained from the P-E loop data. The Pᵣ values reported by Fichtner et al. and Yasuoka et al. are also plotted for comparison. The Pᵣ values monotonically decline with the increase of Sc content. The extrapolated Pᵣ for Sc_{0.20}Al_{0.80}N is about 135 μC/cm², demonstrating the large remnant polarization for the epitaxially grown ScₓAl₁₋ₓN films or layers of the disclosed methods and devices.

Due to the large lattice mismatch between sapphire and GaN, large densities of defects may exist in epitaxial GaN and the ScₓAl₁₋ₓN/GaN heterointerface. To rule out that the hysteresis behavior may be related to any trap charging and discharging processes, retention testing was performed to reveal the stability of the polarization after switching.

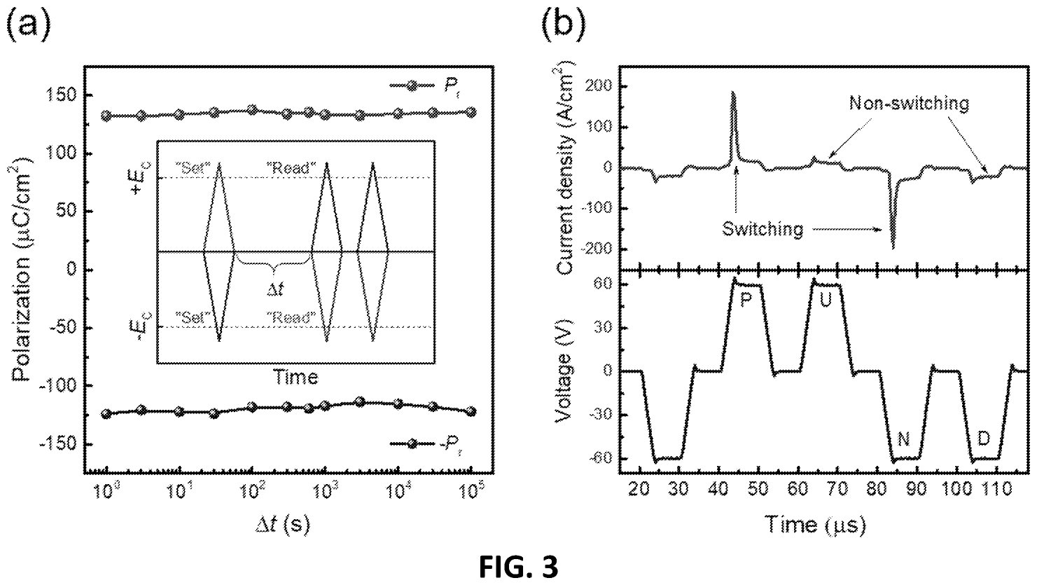

Part A of FIG. 3 displays the retention behavior of an example involving a Sc_{0.20}Al_{0.80}N layer. The remnant polarization in both directions (Pᵣ and −Pᵣ) stayed almost unchanged over 10⁵ seconds(s), indicating little polarization loss and thereby eliminating the possibility of trap-charging effects. The inset shows the voltage pulse sequences used for the retention tests.

Part B of FIG. 3 depicts transient current-voltage profiles during PUND measurements to probe the polarization switching speed of an example of epitaxially grown ScₓAl₁₋ₓN film. In this case, the PUND measurements were captured for the Sc_{0.20}Al_{0.80}N film at 6 MV/cm. Distinct current peaks can be observed in the “P” and “N” sequences. It is also noticed that the current peaks are followed by a stair-like tail, which is mainly from resistive leakage. A sudden current response was measured immediately after the drive voltage saturated, indicating that the polarization switching time is likely significantly smaller than the resolution of the current experimental setup (500 ns).

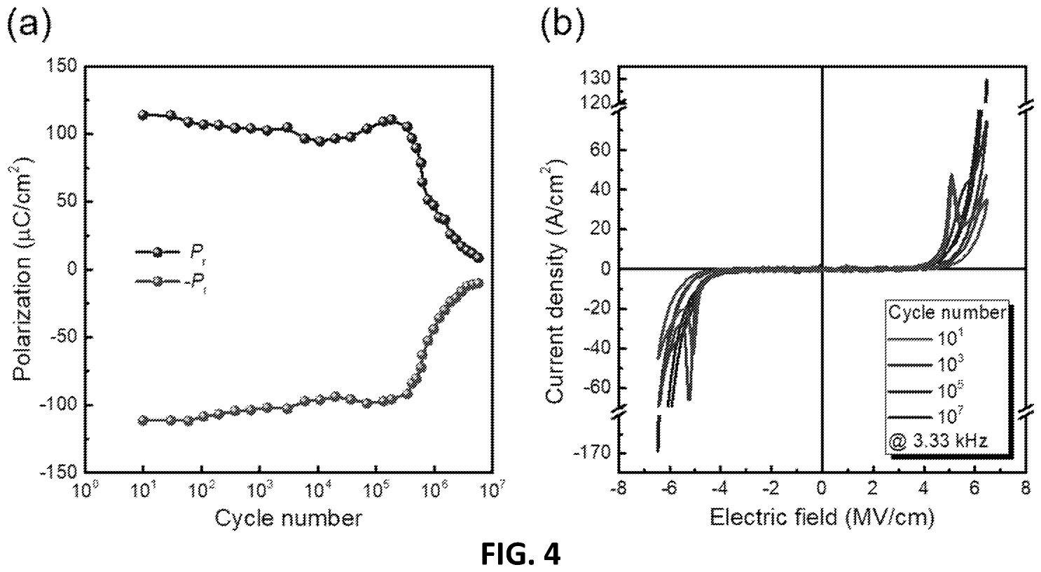

Endurance testing was conducted under 6 MV/cm pulses with a pulse width of 10 us to capture the systematic loss of switchable polarization in a Sc_{0.20}Al_{0.80}N example film under repetitive bipolar cycling. The pulse sequences were pre-executed to make sure that the ferroelectric dipoles were sufficiently realigned under the selected pulse profile. As shown in Part A of FIG. 4, no apparent fatigue behavior can be found with up to about 3×10⁵ switching cycles, which is more than one order of magnitude higher than that of the ScₓAl₁₋ₓN films formed by sputter deposition, and is comparable with conventional ferroelectric materials. After that, the remnant polarization slowly becomes larger and then drops and almost disappears after about 10⁷ switching cycles.

Part B of FIG. 4 shows the J-E loops recorded after 10, 10³, 10⁵, and 10⁷ switching cycles. The polarization switching current gradually decreases and becomes almost invisible with increasing cycle number, while the resistive leakage current exhibits an observable rise. An unexpected increment of coercive field is also measured. The gradual loss of polarization as well as the diminishing of switching current indicates that the polarization fatigue may result from progressive domain wall stabilization by mobile point defects during cycling. This result differs from the fatigue behavior observed on sputter-deposited ScₓAl₁₋ₓN films, in which breakdown occurs after electrical cycling.

Ferroelectricity of ScₓAl₁₋ₓN grown by an epitaxial procedure such as MBE has been achieved. Ferroelectric switching is unambiguously confirmed by systematic electrical measurements on ScₓAl₁₋ₓN films over a Sc content range of about 0.14 to about 0.36. In one case, Sc_{0.20}Al_{0.80}N shows a coercive field of 4.2 MV/cm at 10 KHz and a large remnant polarization of 135 μC/cm². More importantly, the endurance tests exhibit no apparent polarization loss in up to 3×10⁵ switching cycles.

The achievement of epitaxial ferroelectric III-nitride layers (e.g., semiconductor layers), as disclosed herein, may be used to support new and/or improved functionality in III-nitride semiconductor device technologies. A number of examples are described herein. The epitaxial growth of ferroelectric III-nitride layers also creates a number of new device configurations in which ferroelectric functionality is integrated (e.g., seamlessly integrated) into electronic, photonic, optoelectronic, photoelectrochemical, and other devices and systems.

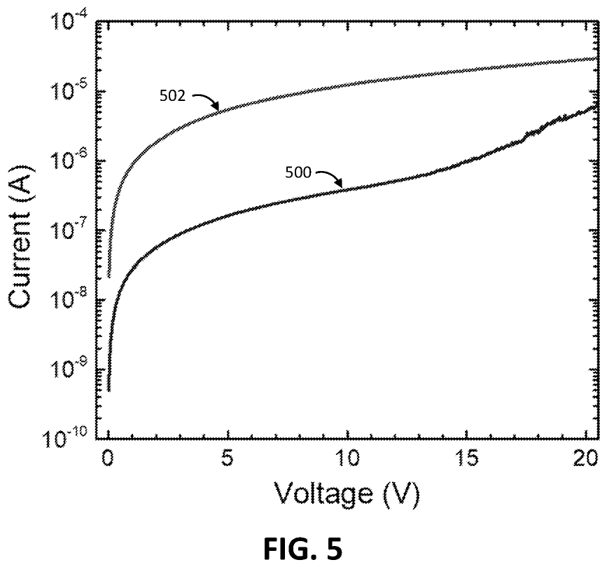

FIG. 5 depicts a comparison of leakage current levels 500, 502 for two ScₓAl₁₋ₓN layers with a same Sc content fabricated in accordance with two examples. The leakage current levels 500, 502 are plotted as a function of applied voltage. One of the wurtzite ScₓAl₁₋ₓN layers was grown with the optimized conditions (e.g., within the growth temperature ranges described herein), and exhibits a leakage current level 500 more than one order of magnitude lower than a leakage current level 502 exhibited by the other layer, which was grown with non-optimized conditions (e.g., above the growth temperature ranges described herein). The significantly reduced leakage current at the level 500 makes it possible to apply an electric field beyond the coercive field of the ScₓAl₁₋ₓN layer, thereby enabling the realization of ferroelectric switching.

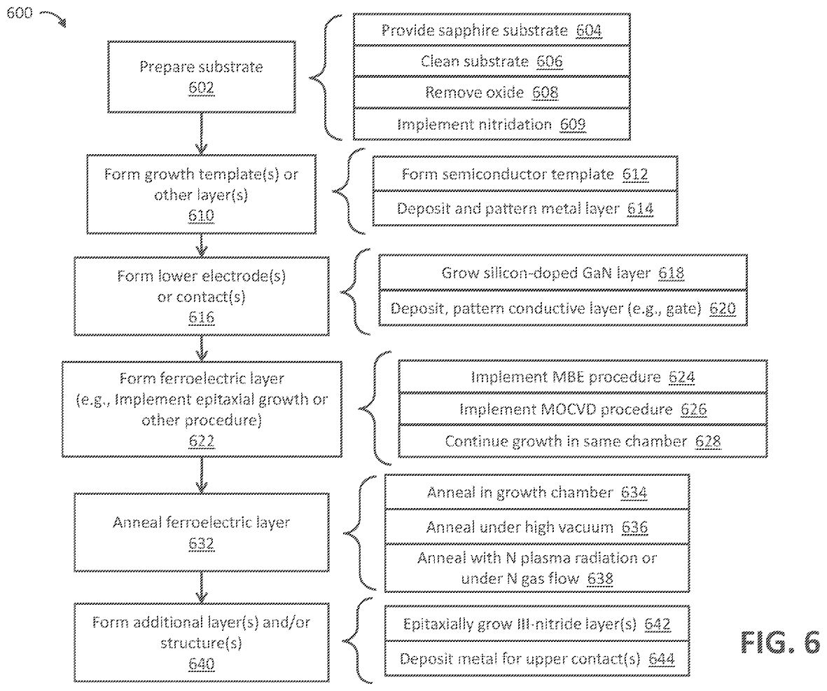

FIG. 6 depicts a method 600 of fabricating a heterostructure having a wurtzite structure of an alloy of a III-nitride material with scandium incorporated therein in accordance with one example. As described herein, the method 600 is configured such that the wurtzite structure exhibits ferroelectric behavior. The heterostructure may form a device, or a part of a device, in which one or more layers or regions of the device exhibit the ferroelectric behavior. The method 600 may be used to fabricate the examples of ScₓAl₁₋ₓN films and layers described herein.

The method 600 may begin with an act 602 in which a substrate is prepared and/or otherwise provided. In some cases, the act 602 includes providing a sapphire substrate in an act 604. Alternative or additional materials may be used, including, for instance, silicon, bulk GaN, bulk AlN, or other semiconductor material. Still other materials may be used, including, for instance, silicon carbide. The substrate may be cleaned in an act 606. In some cases, a native or other oxide layer may be removed from a substrate surface in an act 608. In the example of FIG. 6 (e.g., sapphire examples), the act 602 may include implementing a nitridation procedure in an act 609. Additional or alternative processing may be implemented in other cases, including, for instance, doping or deposition procedures. The substrate thus may or may not have a uniform composition. The substrate may be a uniform or composite structure.

In an act 610, one or more growth templates, buffer, or other layers are formed. The layer(s) are thus formed on, or otherwise supported by, the substrate. The layer(s) may or may not be in contact with the substrate. In some cases, the layer(s) are composed of, or otherwise include, a semiconductor material. For instance, the act 610 may include an act 612 in which a semiconductor layer is formed. For example, a III-nitride layer, such as a GaN layer, may be grown or otherwise formed on the substrate. Other compound or other semiconductor materials may be used, including, for instance, AlGaN. The semiconductor layer(s) may be N-polar or metal-polar. The semiconductor layer(s) may form a part of the heterostructure underlying the ferroelectric layer to be grown. The semiconductor layer be undoped or doped (e.g., Si-doped). The act 612 may thus be implemented before (e.g., in preparation for) implementing an epitaxial growth procedure in which a wurtzite structure is formed. The wurtzite structure may thus be formed on the semiconductor layer. The semiconductor layer may be configured or used as a growth template for the wurtzite structure and/or other elements of the heterostructure. In some cases, the act 612 may include growing the semiconductor layer in an epitaxial growth chamber in which the epitaxial growth procedure for the wurtzite structure is implemented. As a result, the substrate may remain within, e.g., is not removed from, the epitaxial growth chamber between forming the semiconductor layer and implementing the epitaxial growth procedure for growing the wurtzite structure.

Alternatively or additionally, the act 610 includes an act 614 in which one or more metal or other conductive layers are deposited and patterned. For example, an aluminum layer may be deposited on a silicon substrate in preparation for the epitaxial growth of the wurtzite structure.

The method 600 may include an act 616 in which one or more electrodes or contacts or other layers are formed. The layer(s) may form a part of the heterostructure underlying the ferroelectric layer to be grown. Examples of the underlying layer(s) include a lower or bottom electrode or contact of the heterostructure or a channel layer of the heterostructure. The nature of the underlying layer(s) may vary with the device being fabricated. The Si-doped layer may or may not be grown on top of the template or buffer layer formed in the act 610. In the example of FIG. 6, the act 616 includes growing a silicon-doped GaN layer in an act 618. The Si-doped GaN layer may be N-polar or metal-polar. Other materials may be used. For instance, the underlying layer(s) may be composed of, or otherwise include, AlGaN, InAlN, InGaN, or InAlGaN. Still other materials may be used. For instance, a channel layer may be composed of, or otherwise include, other types of semiconductors, e.g., Ga₂O₃, diamond, Si, SiGe, GaAs, InGaAs, or InP, in addition to one or more of the above-referenced III-nitride alloys. The Si-doped GaN layer may act as an electrode layer of a device, such as a memory device. Additional or alternative conductive structures, such as a gate structure, may be deposited and/or patterned in an act 620.

In an act 622, a non-sputtered epitaxial growth procedure is implemented at a growth temperature to form a wurtzite structure supported by the substrate. As described herein, the wurtzite structure is composed of, or otherwise includes, an alloy of a III-nitride material. For instance, the III-nitride material may be AlN. Additional or alternative III-nitride materials may be used, including, for instance, gallium nitride (GaN), indium nitride (InN), and their alloys. As also described herein, the epitaxial growth procedure is configured to incorporate scandium and/or another group IIIB element into the alloy of the III-nitride material. The alloy may thus be ScₓAl₁₋ₓN, for example. In some cases, the act 622 includes an act 624 in which an MBE procedure is implemented. In other cases, an MOCVD or other non-sputtered epitaxial growth procedure is implemented in an act 626.

The act 622 may constitute a continuation, or part of a sequence, of growth procedures. The growth procedures may be implemented in a common, or same, growth chamber. The act 622 may thus include an act 628 in which epitaxial growth is continued in the same chamber in which one or more other layers of the heterostructure were grown. For instance, one or more of the growth template and the underlying semiconductor layer(s) formed in the acts 610 and 616 may be formed in the same chamber as the ferroelectric layer. Sequential layers of the heterostructure may thus be grown without exposure to the ambient. The quality of the interface between the layers may accordingly be improved.

The growth temperature may be at a level such that the wurtzite structure exhibits a breakdown field strength greater than a ferroelectric coercive field strength of the wurtzite structure. Ferroelectric switching and other behavior may thus be achieved.

The growth temperature is at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single crystal of the scandium-including alloy (e.g., a monocrystalline layer of the alloy) at the growth temperature level may nonetheless be achieved. For example, in some cases, a ScₓAl₁₋ₓN alloy may be epitaxially grown at a growth temperature of about 650 degrees Celsius or about 750 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius, about 750 degrees Celsius, or lower than about 650 or 750 degrees Celsius, would result in structures of such poor quality so as to be useless. In contrast, the epitaxially grown ScₓAl₁₋ₓN layer grown at such low temperatures is unexpectedly monocrystalline and of high quality.

Growth of the ScₓAl₁₋ₓN layer at the conventional AlN growth temperature (and other temperatures above the upper bound) unexpectedly results in the formation of dislocations and/or other leakage paths in the ScₓAl₁₋ₓN layer. With the leakage paths, the ScₓAl₁₋ₓN layer has a breakdown field strength level too low (e.g., below the ferroelectric coercive field strength level). The layer accordingly does not exhibit ferroelectric behavior.

In some cases, the growth temperature may be about 650 degrees Celsius or less or about 750 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 680 degrees Celsius, or about 690 degrees Celsius. In still other cases, the upper bound may be lower, including, for instance, about 600 degrees Celsius or about 620 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming ScₓAl₁₋ₓN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

The above-noted differences in crystal quality evidenced via x-ray diffraction rocking curve line widths may also be used to distinguish between monocrystalline and polycrystalline structures. As used herein, the term “polycrystalline” refers to structures having x-ray diffraction rocking curve line widths on the order of a few degrees or higher. As used herein, the term “monocrystalline” refers to structures having x-ray diffraction rocking curve line widths at least one order of magnitude lower than the order of a few degrees.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

The wurtzite structure of the ferroelectric layer may be nitrogen-polar (N-polar) or metal-polar. The polarity of an underlying layer formed in the act 610 and/or the act 616 may be used to establish the polarity of the ferroelectric layer formed in the act 622. The polarity of the underlying layer may, in turn, be established by a characteristic of the substrate. The polarity may continue across the interface between the underlying layer and the ferroelectric layer. Either N- or metal-polarity may thus persist as the composition changes from the underlying layer to the ferroelectric layer.

The wurtzite structure may then be annealed in an act 632. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScₓAl₁₋ₓN may be performed in-situ in the same growth chamber (e.g., the same MBE chamber) in an act 634. In other cases, the annealing is performed ex-situ in a chamber directed to annealing procedures.

The annealing process may be implemented under high vacuum in an act 636 (e.g., in-situ in the growth chamber). In other cases, the annealing may be implemented either with nitrogen plasma radiation or under nitrogen gas flow in an act 638.

The above-described annealing procedure may be implemented in connection with films grown under any of the above-described growth conditions. For instance, the annealing procedure may be implemented after growth under slightly to moderately N-rich conditions at a growth temperature at or below about 650 degrees Celsius, or at or below about 750 degrees Celsius. The annealing procedure may also be implemented after growth under unbalanced flux ratios (e.g., N-rich or extreme N-rich conditions) at growth temperatures above about 650 degrees Celsius or above about 750 degrees Celsius.

The method 600 may include an act 640 in which one or more layers (e.g., semiconductor layers) are formed after growth of the wurtzite structure. As a result, the layer(s) may be in contact with the wurtzite structure. For instance, one or more III-nitride (e.g., GaN or AlGaN) or other semiconductor layers may be epitaxially grown in an act 642. The act 642 may be implemented in the same epitaxial growth chamber used to grow the wurtzite structure. As a result, the substrate (and heterostructure) is not removed from the epitaxial growth chamber between implementing the acts 622 and 640.

Alternatively or additionally, the act 640 includes an act 644 in which one or more metal or other conductive layers or structures are formed. The layers or structures may be deposited or otherwise formed. In some cases, the conductive structure is configured as an upper or top contact. For instance, the conductive structure may be a gate.

The method 600 may include one or more additional acts. For example, one or more acts may be directed to forming other structures or regions of the device that includes the heterostructure. In a transistor device example, the regions may correspond with source and drain regions. The nature of the regions or structures may vary in accordance with the nature of the device.

The order of the acts of the method 600 may differ from the example shown in FIG. 6. For example, the acts 616, 618, and 620 in which contacts and/or other conductive structures formed may be implemented after the growth of the ferroelectric layer.

A number of different types of devices may be fabricated by the method 600 of FIG. 6, and/or another method of fabricating a heterostructure having a wurtzite structure of an alloy of a III-nitride material with scandium incorporated therein. For example, the ferroelectric ScₓAl₁₋ₓN or other alloy of a III-nitride material may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

A number of example devices are now described. In each example, the device includes a substrate and a heterostructure supported by the substrate. The heterostructure includes a monocrystalline layer of an alloy of a III-nitride material. As described herein, the alloy includes scandium. As also described herein, the monocrystalline layer exhibits a breakdown field strength greater than a ferroelectric coercive field strength of the monocrystalline layer. In some cases, the III-nitride material is aluminum nitride (AlN), but other III-nitrides may be used.

In some of the devices described below, the device also includes a semiconductor layer disposed between the substrate and the heterostructure. The semiconductor layer may include a further III-nitride material, such as GaN. In some cases, the semiconductor layer is in contact with the heterostructure. The epitaxial growth of the layers may result in a high quality interface between the layers. Alternatively or additionally, the device also includes a metal or other conductive layer disposed between the substrate and the heterostructure. The metal layer may be in contact with the heterostructure, examples of which are described below.

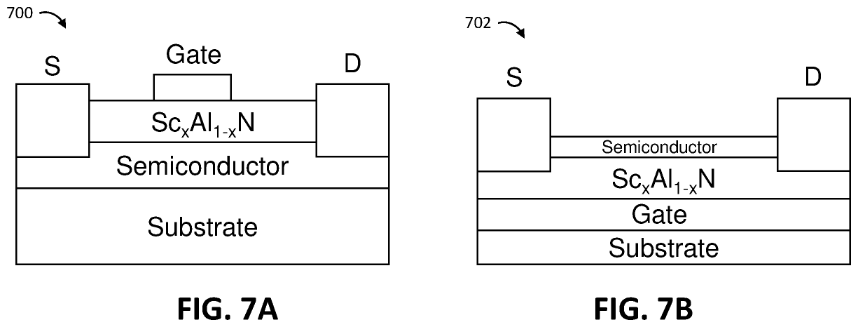

FIGS. 7A and 7B depict examples of FeFET memory devices 700, 702. In each device 700, 702, a ferroelectric ScₓAl₁₋ₓN layer is disposed between a gate electrode and a source-drain conduction region. The ferroelectric layer provides a reversible electrical state for a transistor of the device. The large remnant electrical field polarization in the ferroelectric ScₓAl₁₋ₓN layer retains the state of the transistor (e.g., on or off) in the absence of any electrical bias to form a single transistor nonvolatile memory. In some cases, bulk and/or other semiconductor channel layers are composed of, or otherwise include, GaN or silicon, or two-dimensional materials like MoS₂ or graphene. In each device 700, 702, the FeFET memory device 700, 702 may include a heterostructure including, for instance, the ferroelectric ScₓAl₁₋ₓN or other alloy of a III-nitride material, along with one or more layers of a III-nitride semiconductor, such as AlN, as the gate dielectric and barrier. The substrate supporting these layers and structures of the devices may be composed of, or otherwise include, for instance, GaN or silicon. The control terminal or gate may be disposed above or below the heterostructure as shown.

Other types of memory devices include one transistor one capacitor (1T-1C) FeRAM devices. For example, a FeRAM device may include a MIM ferroelectric capacitor composed of, or otherwise including, Al, ScₓAl₁₋ₓN, and Al supported by a pre-processed silicon or GaN substrate.

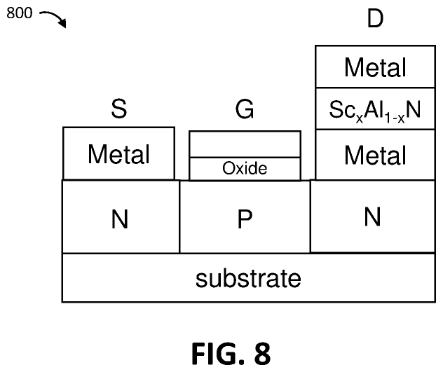

FIG. 8 depicts a coupled FET structure 800 configured as a memory cell. During the switching of the remnant polarization state in a ScₓAl₁₋ₓN layer, a current pulse is generated to indicate the stored binary information in the cell.

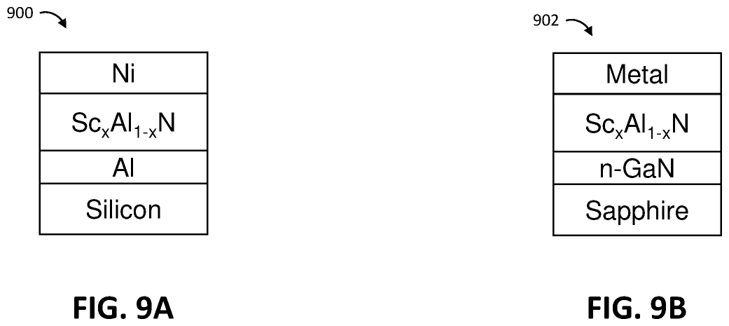

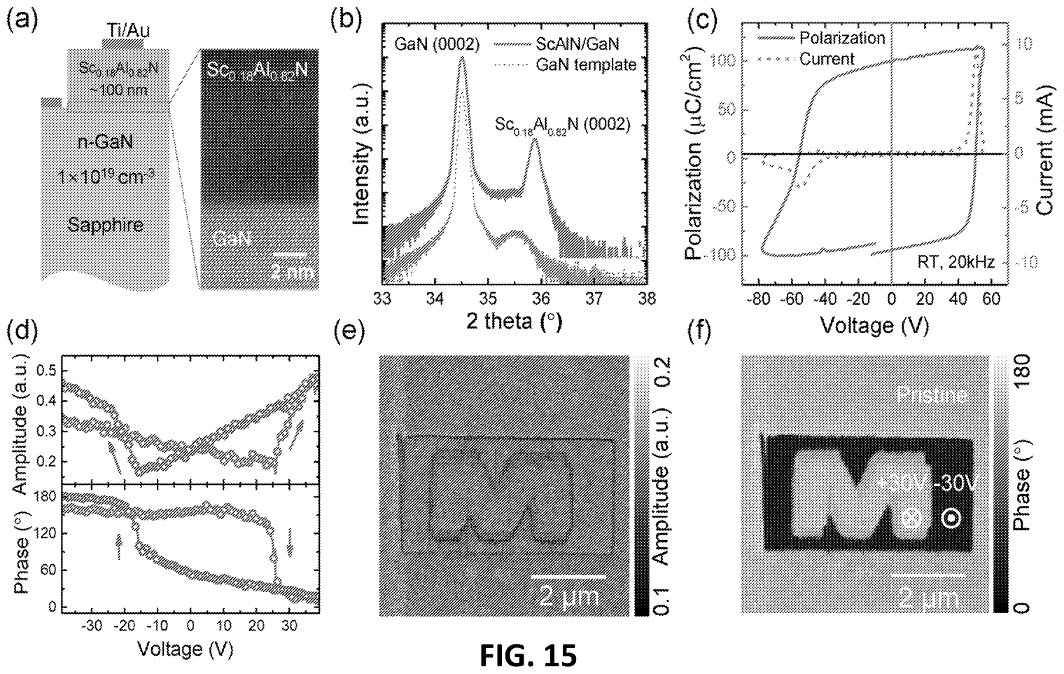

FIGS. 9A and 9B depict examples of FTJ memory devices 900, 902. In the example device 900, an epitaxially grown ferroelectric layer is disposed between metal layers (e.g., nickel and aluminum layers). In the other example device 902, the ferroelectric layer is disposed between a III-nitride semiconductor layer (e.g., n-type doped GaN) and a metal layer. Other metal-Fe (insulator)-metal and metal-(insulator)-Fe-(insulator)-semiconductor configurations may be used. In these example devices 900, 902, the ScₓAl₁₋ₓN or other alloy provides the ferroelectricity and tunes the ON/OFF current/resistance ratio as a memorizer readout. Further details regarding additional examples of memory devices having a heterostructure with a ferroelectric layer composed of, or otherwise including a III-nitride alloy, as well as methods of using such memory devices, are provided below in connection with FIGS. 15-21.

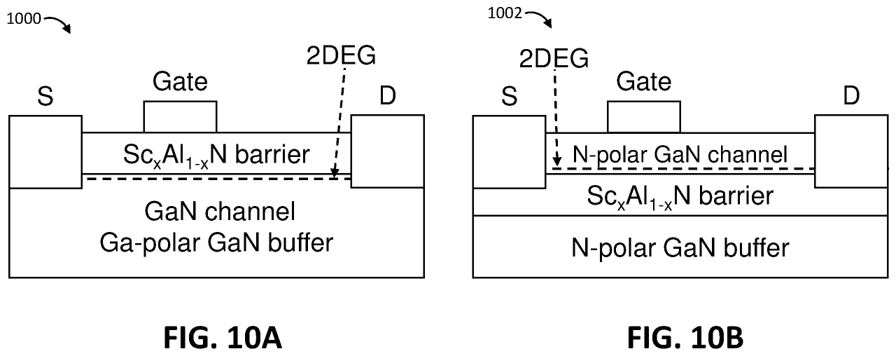

FIGS. 10A and 10B depict examples of metal-polar and N-polar Fe-HEMT devices 1000, 1002, respectively. In these two examples, each of the devices 1000, 1002 includes a heterostructure composed of, or otherwise including, a stack of ferroelectric ScₓAl₁₋ₓN, channel, and buffer layers. The order or arrangement of the layers varies as shown between the metal-polar and N-polar examples. The heterostructure may include additional, fewer, or alternative layers. For instance, the N-polar buffer layer shown in the device 1002 of FIG. 10B may be grown on an additional, underlying Si-doped N-polar III-nitride layer, such as an Si-doped, N-polar GaN layer.

The heterostructure may be grown on a bulk or other region composed of, or otherwise including, a III-nitride semiconductor material, such as GaN. One or more of the III-nitride semiconductor layers may be doped, e.g., Si or otherwise n-type doped. Other III-nitride semiconductors may be used, including, for instance, AlGaN, InGaN, and InAlGaN as described herein. A switchable two-dimensional electron gas (2DEG) heterojunction may thus be formed due to the strong spontaneous polarization in the ScₓAl₁₋ₓN layer during operation as shown. A thin AlN layer may be inserted between the ScₓAl₁₋ₓN and channel layers to enhance carrier mobility.

Still other types of transistor devices may utilize the epitaxially grown ferroelectric layers described herein, including, for instance, N-polar bottom-gated and gate-recessed transistor devices, both with and without a gate oxide layer.

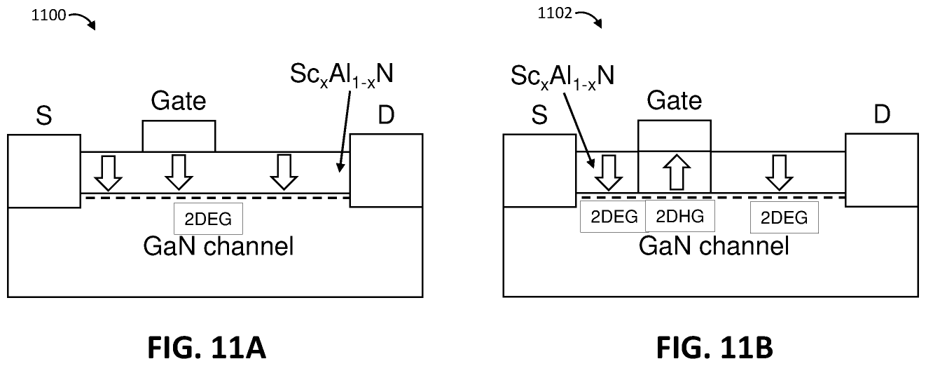

FIGS. 11A and 11B depict examples of reconfigurable Fe-HEMT devices 1100, 1102. In these examples, each of the devices 1100, 1102 includes a heterostructure with a ferroelectric ScₓAl₁₋ₓN layer. As shown in FIG. 11A, the heterostructure may include a stack of ferroelectric ScₓAl₁₋ₓN and channel layers, in which the polarization of the ferroelectric ScₓAl₁₋ₓN layer can be switched. Alternatively, the heterostructure may be configured such that a 2DHG or depletion region underlying the polarization switched region is formed, as shown in FIG. 11B. The disclosed devices include still other types of reconfigurable Fe-HEMT devices, including, for instance, Fe-HEMT devices including the N-polar structure depicted in FIG. 10B.

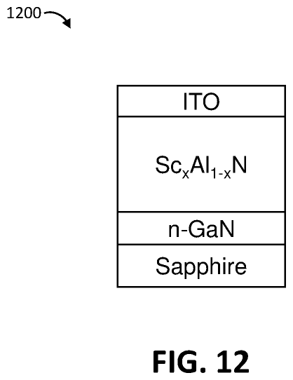

FIG. 12 depicts an example of a photovoltaic device 1200 in which a ferroelectric layer is integrated into a heterostructure having one or more III-nitride layers between electrodes of the device. In the example shown, the heterostructure includes an n-type GaN layer adjacent to, and in contact with a ScₓAl₁₋ₓN layer. An indium tin oxide (ITO) layer establishes one of the electrodes (e.g., a transparent cathode or anode) of the device. Photon-generated carriers in the ScₓAl₁₋ₓN layer are separated and collected by the polarization-induced electric field. The heterostructure may be supported by a sapphire or other substrate.

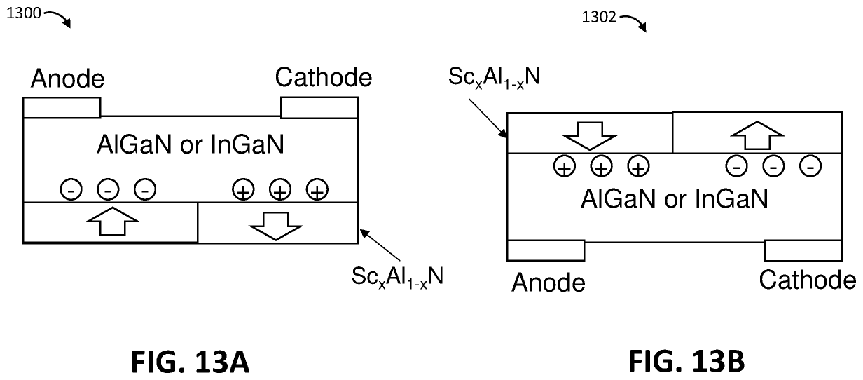

FIGS. 13A and 13B depict further examples of photovoltaic devices 1300, 1302. In each example, the polarization in a ferroelectric layer attracts electron/hole charges to different regions, thereby creating a built-in electric field in a light-absorption layer and helping to separate and collect the photon-generated carriers.

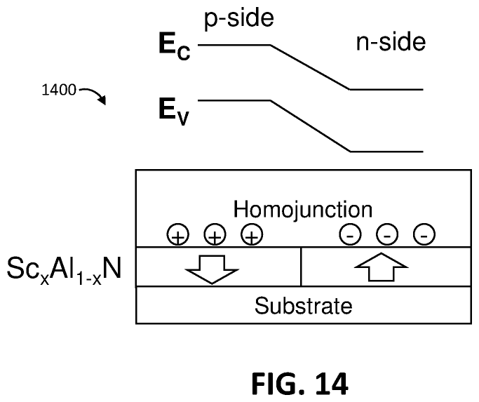

FIG. 14 depicts an example of a homojunction device 1400 having a ferroelectric layer adjacent a channel layer or region. The modulated polarization in the ferroelectric layer attracts electrons and holes in opposite directions, thereby forming a lateral homo p-n junction inside the channel material. The homojunction may be formed in semiconductors such as GaN, Si and two-dimensional materials.

Described above are devices and structures exhibiting ferroelectricity, e.g., in layers of ScₓAl₁₋ₓN. Methods for growing the structures are also described, including methods involving, for instance, plasma-assisted molecular beam epitaxy on GaN templates. Distinct polarization switching is unambiguously observed for ScₓAl₁₋ₓN films with Sc content in the range of, e.g., 0.14-0.36. Examples of Sc_{0.20}Al_{0.80}N, which is nearly lattice-matched with GaN, were found to exhibit a coercive field of about 4.2 MV/cm at 10 KHz and a remnant polarization of about 135 μC/cm². After electrical poling, an example of Sc_{0.20}Al_{0.80}N presented a polarization retention time beyond 10⁵ seconds. Furthermore, no apparent fatigue behavior was found with up to 3×10⁵ switching cycles. The realization of ferroelectric III-V semiconductors using molecular beam and other epitaxy allows for thickness scaling, e.g., into the nanometer regime, as well as integration of high-performance ferroelectric functionality with well-established semiconductor platforms for a broad range of electronic, optoelectronic, and photonic device applications.

Ferroelectric Memory Devices. The above-described heterostructures with a ferroelectric layer composed of, or otherwise including, a III-nitride alloy, and methods of forming such heterostructures, may be used to fabricate ferroelectric memory devices. In some cases, the heterostructures may include a heterointerface established by a ScAlN film and a GaN layer in contact therewith. Set forth below are further details regarding ferroelectric memory devices in connection with a number of examples.

Electrically switchable bistable conductance that occurs in ferroelectric materials has attracted growing interest due to its promising applications in data storage and in-memory computing. Sc-alloyed III-nitrides have emerged as a new class of ferroelectrics, which not only enable seamless integration with III-nitride technology but also provide an alternative solution for CMOS back end of line integration. Examples of resistive switching behavior and memory effect in an ultrawide-bandgap, high Curie temperature, fully epitaxial ferroelectric ScAlN/GaN heterostructure are described below. The examples exhibited robust ON and OFF states that last for months at room temperature with rectifying ratios of 60-210, and further showed stable operation at high temperatures (e.g., about 670 K) that are close to or even above the Curie temperature of most conventional ferroelectrics. Analysis of the examples indicates that the underlying mechanism is directly related to a ferroelectric field effect induced charge reconstruction at the hetero-interface. The robust resistive switching landscape and the electrical polarization engineering capability in the polar heterostructure, together with the promise to integrate with both silicon and GaN technologies, may be useful in next-generation memristors and other multifunctional and cross-field applications.

Ferroelectric materials exhibit a spontaneous polarization that can be reoriented by an external electric field, the principle of which has been used to modify the barrier height or width in a metal-ferroelectric-metal capacitor or a ferroelectric/semiconductor heterostructure to make resistive switching memristors and programmable homojunctions. With the increasing demand in big data storage and data-centric computing, there have been significant interests in ferroelectric resistive switching devices due to their promising applications in energy efficient memory, neuromorphic and in-memory computing, and edge intelligence. As a result, tremendous efforts have been devoted to fabricating resistive switching devices including ferroelectric tunnel junctions (FTJs), ferroelectric field effect transistors (Fe-FETs), and ferroelectric diodes based on the conventional perovskite- or fluorite-type ferroelectrics, as well as various newly discovered two-dimensional ferroelectric materials. On the process side, with silicon technology being the mainstream, the rigorous processing steps and strict elements control within the CMOS production line pose major challenges to the materials available for making ferroelectric memristors toward marketization. On the material side, the low Curie temperature, small coercive field and narrow bandgap of most conventional ferroelectrics make related devices susceptible to strain/stoichiometry distortions, read/write operation, depolarization field and charge injection, etc., resulting in limited memory window and stability issues especially under harsh environments. The demonstration of ferroelectricity in doped hafnium oxide and zirconium oxide and their alloyed variants brought new life to the ferroelectric memory community by being standard materials used in CMOS processes and has directed the boom in Fe-FETs, FTJs and negative-capacitance FETs (NC-FETs) in the past decade.

Sc-alloyed wurtzite III-nitrides (Sc-III-Ns) have emerged as new members of the ferroelectrics family with high temperature phase stability (up to 1100° C.), large tunable coercive field (1.5-6 MV cm⁻¹), remarkable switchable polarization (80-120 μC cm⁻²), wide bandgap (4.9-5.6 eV), and unprecedented resistance to retention even on a polar semiconductor electrode, making these new materials candidates for memory applications that may outweigh conventional ferroelectrics in terms of lifetime and stability especially in harsh environments. The wide synthesizing window also raises interests in a post-CMOS compatible processing technology. In spite of these promises, there have been few demonstrations of ScAlN memory devices, which were only realized by using sputter deposition.

Compared to conventional sputter deposition, the above-described epitaxial growth of ferroelectric ScAlN by molecular beam epitaxy (MBE) is useful in several ways, including superior control over crystallinity, stoichiometry, thickness, doping, interface, and uniformity. These characteristics are, in turn, useful for the performance, stability, and yield of memory cells, arrays, and other devices. The single-crystalline nature of MBE-grown ScAlN can further offer a useful approach to control the threshold variation, which has remained an unresolved issue for “the era of ferroelectrics”. Moreover, the fully epitaxial method and the electrically switchable polarization greatly extend the spontaneous/piezoelectric polarization engineering space in III-nitrides, and further promise a seamless integration of ferroelectricity with the outstanding properties of III-nitrides and nitride-based electronics, optoelectronics and piezoelectronics, which may be useful in connection with all-nitride based energy-efficient memory circuits and edge-intelligence (EI) applications for harsh environments. Moreover, given the mature nitride-on-silicon technology, high quality ScAlN films and other layers can be readily grown on Si substrates over a wide range of growth conditions, enabling seamless integration with Si-based memory applications and other devices.

In support of these applications and devices, the examples described below demonstrate the ferroelectricity and polarization engineering in Sc-III-N/III-N heterostructure devices. In one example, a fully epitaxial ferroelectric ScAlN/GaN heterostructure memory device has been realized. The coupling between the distinct resistive switching behavior and polarization orientation is further analyzed in detail. The structure exhibits robust ON and OFF states depending on electrical poling directions at room temperature, with an ON/OFF ratio of 60-210, retention time of over 3×10⁶ s, and bipolar cycling of over 10⁴ times. Polarization-resistance correlated measurements provided direct evidence of a ferroelectric polarization coupled resistive switching process. The conductance and capacitance rectifying ratios were found to decrease with increasing carrier concentration in the GaN electrode layer, suggesting a ferroelectric field effect induced charge reconstruction at the heterointerface, an effect useful for incorporating ScAlN into III-nitride devices. Furthermore, the memory effect exhibited weak dependence on operation temperature. A maximum rectifying ratio of about 10 is well maintained even at 670 K, a temperature range that is close to, or even higher than the Curie temperature of most conventional ferroelectrics. These analyses establish ScAlN based ferroelectric/III-nitride heterostructures as a useful candidate for ferroelectric-resistive memory devices, including next-generation memristors and all nitride-based monolithic integrated circuits for energy-efficient applications and harsh environments.

In one set of examples, single crystalline ScAlN films with a thickness of about 100 nm were grown on commercial GaN/sapphire templates by radio-frequency plasma-assisted MBE following the growth of a Si-doped GaN bottom electrode layer with a thickness of about 120 nm and a carrier concentration of about 1×10¹⁹ cm⁻³. Ti/Au metal pillars with different diameters (3-50 μm) were then deposited as top electrodes, as schematically shown in Part (a) of FIG. 15. The Sc content of the ScAlN layer was set to about 18% to match the lattice of GaN to reduce misfit defects and dislocations. The heterostructures were fabricated as described herein. Further details regarding fabrication are provided below.

FIG. 15 presents results collected from an example with a GaN electrode carrier concentration of about 1×10¹⁹ cm⁻³ and top electrode diameter of 20 μm (unless otherwise specified). As shown in the scanning transmission electron microscopy (STEM) image on the right side of part (a) of FIG. 15, an atomically ordered interface can be observed, showing good epitaxial quality. Part (b) of FIG. 15 depicts the X-ray 2θ-ω scans on one ScAlN/n-GaN example. The characteristic diffraction peak for ScAlN (0002) can be observed clearly, further confirming the wurtzite structure of the ScAlN film. The (0002) plane rocking curve full-width-at-half-maximum values (FWHMs) of all the ScAlN films were less than 400 arcsec, which is nearly one order of magnitude smaller than conventional sputtering and further confirms the excellent structural property. Part (c) of FIG. 15 displays the typical current-voltage (I-V) and polarization-voltage (P-V) hysteresis loops recorded using Radiant ferroelectric tester II at 20 KHz at room temperature. The remnant polarization was estimated as about 90 μC cm⁻², consistent with previous reports. The asymmetry in the P-V loop is ascribed to asymmetric electrode material. The ferroelectricity in the ScAlN/GaN heterostructure was also confirmed by piezo-response force microscopy (PFM). As shown in part (d) of FIG. 15, the butterfly-shape amplitude diagram and the box-shape phase diagram with approximately 180° separation suggested that the polarity of the film can be switched externally by an electric field. Parts (e) and (f) of FIG. 15 further show the PFM out-of-plane phase and amplitude images of domains after writing at +30 V and mapped at V_{AC}=0.6 V, 30 KHz. The 180° phase contrast, clear domain boundary and uniform contrast in each poled region manifest that stable antiparallel domains can be written in the ScAlN layer. The low amplitude signal along the domain boundary indicates the cancelling contribution of opposite domains, which is characteristic of ferroelectrics. Those patterns were still detectable after 24 hours, showing the stability of the polarity switched domains.

FIG. 15 thus depicts the ferroelectricity in the epitaxial ScAlN/GaN heterostructure example. The pristine piezoelectric phase exhibited the same contrast with the patterns written by +30 V, indicating a downward polarization, which agrees with the polarity of the substrate. The contrary phase under the same poling direction in parts (d) and (f) stems from the phase value renormalization with different initial phase states during measurements.

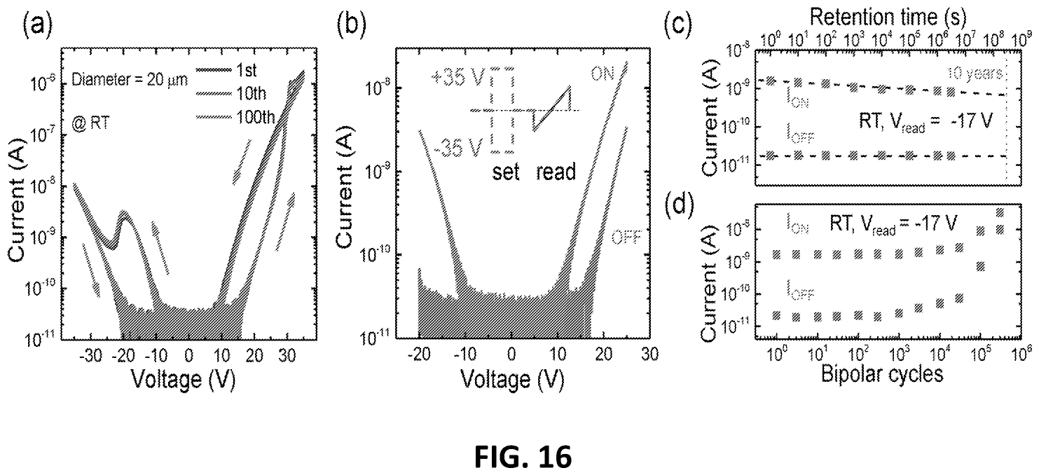

FIG. 16 depicts the resistive switching behavior in the example ScAlN/GaN heterostructure memory device of FIG. 15. To investigate the resistive switching behavior, static I-V hysteretic loops were measured by a B1500 semiconductor analyzer at room temperature with a step size of 100 mV. All voltages were applied to the top electrode while the bottom electrode was grounded. The scan direction followed −35 V, then 35 V, then −35 V. As shown in part (a) of FIG. 16, the device exhibited clear, stable bipolar hysteresis loops with good repeatability, which remained virtually unchanged after 100 bipolar scans. A high current state is exhibited when sweeping back from positive bias, while a low current state is exhibited when scanning back from negative bias, manifesting a counterclockwise-clockwise rotation direction.

Part (b) of FIG. 16 is directed to show the non-destructive reading of the ON/OFF current, with the inset showing the measurement sequence. Part (b) shows the current measured at small voltages after poling by voltage pulses. Under a poling pulse of +35 V (20 ms in width) on the top electrode, a high current state, namely the ON state, is established, featuring high current densities under both bias directions. Then, after a poling pulse of −35 V (20 ms in width), a low current state, or the OFF state, is achieved, giving a rectification ratio of about 100 at a read voltage level of −17 V. The OFF current exhibits diode-like conduction, i.e., the current under positive bias is larger than that under negative bias, while the ON current looks more symmetric with almost identical absolute turn on voltages (+10 V).

For some of the devices, a relatively low OFF current or large ON current was measured during the first several scans, resulting in ON/OFF ratios exceeding 10⁴. However, after several scans, the I-V curves stabilized and all devices showed no difference with those shown in part (a) of FIG. 16, indicating very good uniformity.

Part (c) of FIG. 16 is directed to the retention properties of the device examples. The non-volatile nature of the ON and OFF states was explored by measuring the device current at −17 V after pulse poling for different retention times. As shown in part (c), a slight decrease in ON current is noticed, while the OFF current remains stable possibly due to the detection limit. An ON/OFF ratio of about 46 can still be retained after more than a month (3×10⁶ s) with a projected lifetime of over 10 years.

Part (d) of FIG. 16 is directed to the testing of the bipolar switching characteristics of the ScAlN/GaN heterostructure. The characteristics were tested by poling the ScAlN/GaN heterostructure repeatedly with +35 V pulses and reading the current at −17 V. As shown in part (d), the ON and OFF current remain steady over 10⁴ write/read cycles, and both increase drastically after about 10⁵ write/read cycles. The increase in OFF current is faster than in ON current, causing rectifying ratio to drop from about 100 to about 10 after 10⁵ bipolar switching cycles. Polarization fatigue measurements showed sizeable remnant polarization with up to 10⁷ switching cycles. The early setting-in of resistive fatigue could be related to charge injection to the ScAlN/GaN interface. With a larger negative poling voltage, or longer negative voltage poling time, the increased OFF current can be partly restored.

These results nevertheless show the great potential of ScAlN/GaN heterostructures as memory devices.

Taken together, the graphical plots shown in FIGS. 15 and 16 show that positive poling, after which polarization points downward, corresponds to the ON state, while upward polarization corresponds to the OFF state. To elucidate the relationship between resistive switching and ferroelectric switching, a modified write/read process may be used. For instance, first, a preset pulse (+35 V, 20 ms) is used to set the device to OFF (ON) state. Then a voltage and width-tunable write pulse is applied followed by a non-destructive current readout. Finally, two identical trapezoidal waveforms (switching+non-switching) were used to extract the polarization change. In this scenario, the conductivity of the heterostructure, and the polarization state corresponding to this conductivity, can be obtained simultaneously after each writing pulse.

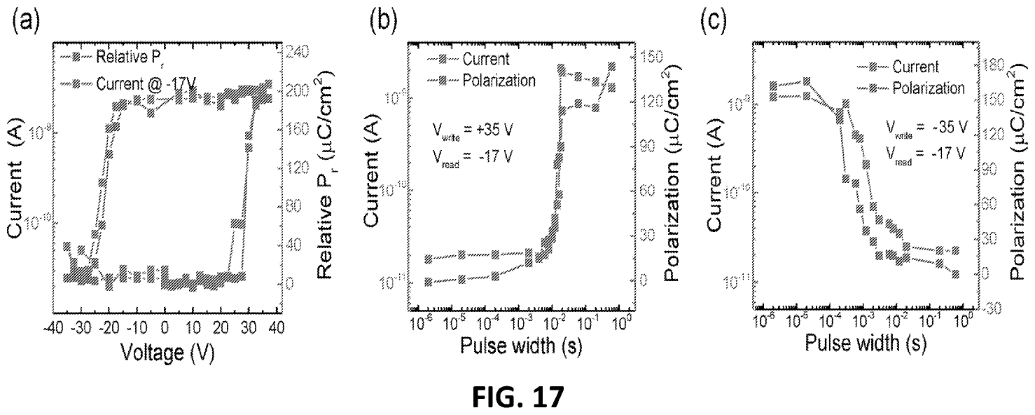

As shown in part (a) of FIG. 17, the hysteretic resistive switching of the device exhibited almost identical shape with the P-V loop, with nearly the same threshold voltage and saturation behavior, which provides clear and direct evidence of a ferroelectric polarization modulated resistive switching process. Parts (b) and (c) of FIG. 17 further showed the writing pulse width dependence of the resistive switching and polarization switching process. When the writing pulse width is small, negligible polarization or conductivity change is noticed. As the writing pulse width increases, the polarization difference before and after writing pulse slowly increases and saturates at 2Pᵣ when pulse width is over certain values. The device current level, sensed at −17 V, shows the same trend. These results show a ferroelectric polarization orientation modulated resistive switching behavior in the ScAlN/GaN heterostructure. The gradual modulation of conductance with different pulse widths may thus be further used to provide memory arrays and other devices with modulated memory states. Such modulation may be used to mimic a biological learning rule called spike-timing-dependent plasticity (STDP).

FIG. 17 depicts the simultaneous measurement of conductivity and polarization change. In part (a) of FIG. 17, the conductivity hysteresis loop of the ScAlN/GaN heterostructure example is shown with the corresponding relative polarization state. Two branches are plotted together to form a complete loop. In parts (b) and (c), pulse-width dependent measurements are shown. In this case, a preset pulse first sets the device to OFF (ON) state. Then a tunable write pulse is applied followed by a non-destructive current readout. Finally, two fixed trapezoidal waveforms are used to probe the relative polarization change after the write pulse.

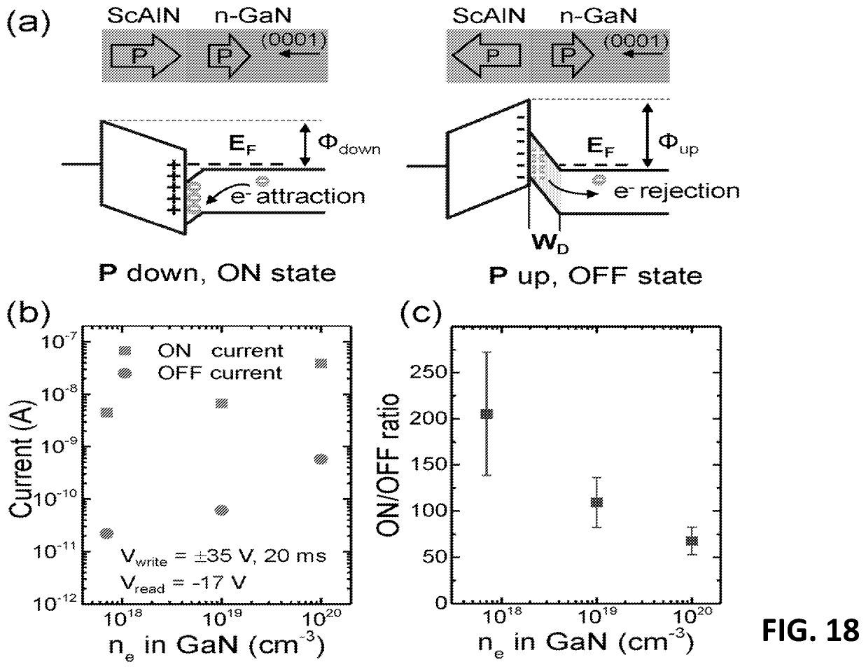

Part (a) of FIG. 18 depicts schematics of energy band diagrams of a ScAlN/GaN heterostructure example modulated by the polarization orientation in the ScAlN layer. Pup, Φ_{down} are the effective barrier heights for electron transport. Due to the ferroelectric field effect and charge screening, a space charge region and a higher effective barrier are built during polarization P up operation. In part (b), the dependence of ON/OFF current on carrier concentration in the GaN contact layer is shown. In part (c), the corresponding ON/OFF ratio is shown. Error bars in c) are standard deviations calculated from 10 different devices in each sample. Measurements were done with 50-μm-diameter top electrodes to enable better comparison of the OFF current. The spread of ON/OFF ratios with decreasing GaN carrier concentration indicates an enhanced effect of depolarization field

The band diagrams for the ScAlN/GaN heterostructure are provided to explain the experimentally observed I-V hysteresis loops. The ferroelectric field effect and real-space charge reconstruction at the ScAlN/GaN interface were taken into consideration. As schematically shown in part (a) of FIG. 18, due to the ferroelectric field effect, when the ferroelectric polarization in ScAlN is downward after positive pulse writing, the positive polarization charges at the ScAlN/GaN interface will attract electrons near the interface and cause a downward bending of the band profile and an accumulation region; when the ferroelectric polarization in ScAlN is upward after negative pulse writing, the negative polarization charges at the ScAlN/GaN interface will repel electrons near the interface, leading to an upward bending of the band profile as well as a depletion region. In the latter case, the total barrier height is increased, and an additional interface barrier is presented, which blocks the electron transport and results in the OFF state.

This behavior is confirmed by growing ScAlN on GaN with different doping concentrations. As shown in part (b) of FIG. 18, both ON and OFF current increases with increasing carrier concentration in the GaN electrode. As the OFF current increases faster, the maximum ON/OFF ratio drops from about 210 to 60 when the carrier concentration of the n-GaN layer increases from about 7×10¹⁷ cm⁻³ to about 1×10²⁰ cm⁻³. This behavior arises because, in the ON state, the polarization is downward and the interface is already in accumulation. Further filling the interface with electrons causes negligible lowering of the barrier height. While in the OFF state, the polarization is upward, and the screening of the polarization charge is strongly enhanced by the high doping concentration in the electrode layer, consequently a more pronounced reduction of the depletion region width and the interfacial barrier height.

The depletion widths were calculated based on capacitance-voltage (C-V) measurements at small voltages, indicating a reduction of equilibrium depletion width from about 10 nm to less than 1 nm when the carrier concentration increases from about 7×10¹⁷ cm⁻³ to about 1×10²⁰ cm⁻³, consistent with the behavior proposed above. Fitting of the experimental I-V data indicates a linear dependence of In(I/V) on the square root of V. However, the extracted relative dielectric constant using Poole-Frenkel emission model (in the range of 6 to 8) is much smaller than that from C-V measurements (about 12), suggesting the conduction involved here is not dominated by polarization coupled trap-filling-factor change reported previously for a metal/ScAlN/metal capacitor. The fast increase of current with voltage could indicate certain extent of tunneling current from the triangular barrier formed at the electrode/ferroelectric interface due to strong applied electric field. Instead, the Poole-Frenkel emission model is found to fit the I-V curves very well after resistive fatigue, indicative of a transition from interface barrier modulated conduction to bulk Poole-Frenkel emission limited transport after cycling. It is suspected that during bipolar cycling, excessive charges are injected to the ScAlN/GaN interface, which lowers the overall barrier height and causes leakage paths. This explains the early setting-in of resistive fatigue and the restoration behavior considering that charge injection has been reported to occur before domain wall pinning and could be partially released upon back-filling or heating. Besides, the shape of the I-V hysteresis loop is found to be independent of the electrode material, which further shows that the rectifying effect stems from the ScAlN/GaN interface, rather than from a Schottky barrier. Due to the large oxygen affinity of Sc and Al, there could be a thin oxide layer between the top electrode and ScAlN surface. If the conduction is modulated by the barrier height of the thin oxide layer, altering the electrode material may also change the work function of the electrode thereby the electrode-oxide interface barrier height, resulting in different rectifying ratios. However, this was not observed. Those results together validate a ferroelectric field effect dominated resistive switching in the ScAlN/GaN heterostructure.

The depletion widths extracted are much smaller than the values from theoretical calculation considering the large polarization discontinuity and an ideal ScAlN/GaN interface. The polarization charge at the interface could be slightly screened by interface traps introduced either during growth interruption or from the low purity Sc source (99.9%). Moreover, due to the strong chemical bonding at the ScAlN/GaN interface and the relatively small dielectric constant of ScAlN (thus stronger depolarization field), a thin non-switchable paraelectric ScAlN layer or pinned domains could be present, which significantly compensates the overall switchable polarization and weakens the ferroelectric field effect, leading to excessively attenuated depletion widths. The latter is believed to be the main reason for the tailored depletion region in the examples described herein. Besides, vacancies could also accumulate at the interface and screen the polarization charges. Nevertheless, an effective remnant polarization may be introduced to quantitatively depict the charge reconstruction at the interface.

Due to significant electromigration of oxygen vacancies, filament conduction or electronic conductor-insulator transition could occur and dominate or contribute to the resistive switching process in ferroelectrics. In the examples described herein, the complete reorientation of the wurtzite structure involves a holistic displacement of metal or nitrogen atoms, which may evoke some vacancy migration events. However, by varying the diameter of the electrodes from 3 μm to 50 μm, the I-V hysteresis loop was found to be independent of junction area, and no electroforming or current compliance was required to stabilize the switchable resistance, thereby excluding the formation of conductive filaments. On the other hand, the ON current in the examples described herein appears symmetric and is always larger than the OFF current under both biasing conditions, which is different from the typical diode-like hysteresis loop during electronic conductor-insulator transition. Besides, the electromigration model by itself is bulk conduction and cannot account for the carrier concentration dependence shown in parts (b) and (c) of FIG. 18. Therefore, it follows that for the ScAlN/GaN heterostructure examples described herein, electromigration of defects like vacancies could exist but is not playing a significant role.

The disclosed devices are capable of operation at high temperatures. A wide bandgap of about 5.5 eV has been reported for ScAlN with 18% Sc content, which is above most of the ferroelectric materials reported. Besides, the conduction band offset between ScAlN with 18% Sc content and GaN is predicted to be about 1.74 eV from first-principle calculations and about 2.09 eV by X-ray photoelectron spectroscopy (XPS) measurements. Those wide-bandgap characteristics, carrying over to ScAlN from III-nitrides, are expected to help suppress thermally activated current at high temperatures.

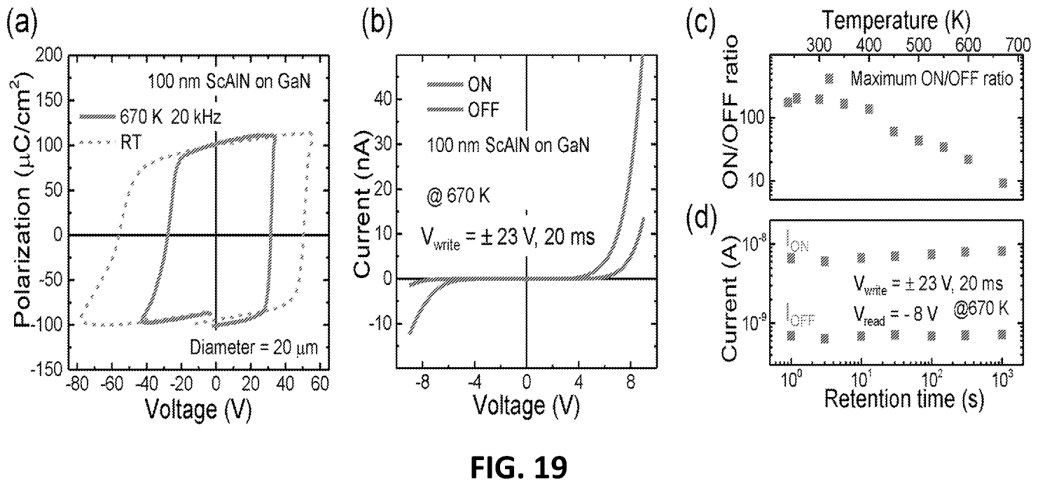

FIG. 19 depicts high temperature performance of a ScAlN/GaN heterostructure memory device in accordance with one example. In part (a), a P-V loop for operation at 670 K on a hotplate is shown. In part (b), ON and OFF current levels are depicted for operation probed at 670 K, showing bistable conductivity. In part (c), the dependence of the ON/OFF ratio on operation temperature is shown. Due to the strong temperature dependence of the coercive field, the write and read voltage were gradually reduced with increasing temperature. The ON/OFF ratio is calculated as the maximum ON/OFF ratio in the non-destructive I-V readout. Part (d) depicts the results of a retention test at 670 K on a hotplate using Keithley 2400.

Part (a) of FIG. 19 compares the P-V loops at room temperature and at 670 K. A drastic drop of coercive field is observed at 670 K, while the remnant polarization keeps steady. The writing pulse was consequently modified to ±23 V, 20 ms. Surprisingly, even at 670 K, the ON/OFF states are still attainable with a rectifying ratio of about 10, as depicted in part (b) of FIG. 19. This temperature is already quite close to the Curie temperature of many ferroelectric materials including HfO₂. In this case, the highest testing temperature was limited by the setup available. Thus, still higher operating temperatures are accordingly possible. Additionally, it is worth mentioning that most of the integrated circuits based on Si technology have operated up to 400° C., which higher than or close to the Curie temperature of most conventional ferroelectrics. Therefore, these results demonstrate that the ScAlN/GaN-based memory devices and other examples described herein are compatible with the Si integrated circuits suitable for harsh operating environments, such as high temperature operation.

Part (c) of FIG. 19 further delineates the temperature dependence of the maximum ON/OFF ratio for the ScAlN/GaN heterostructure memory. With the increase of ambient temperature, the maximum ON/OFF ratio drops slowly from about 200 to 10 at 670 K, in contrast with the rapid decrease of ON/OFF ratios in a BaTiO₃ based FTJ device. The stability of the two states at high temperature is shown in part (d) of FIG. 19, indicating a retention time over 10³ s at 670 K. After optimization, an ON/OFF ratio of about 100 was still obtained even at 433° C. Those results confirm the superior stability of ScAlN/GaN based memory devices, and provide a viable path for realizing memory devices for harsh environments such as aerospace and military applications.

The heterostructures of the example memory devices described above were grown using a Veeco GENxplor MBE system equipped with a radio-frequency (RF) plasma-assisted nitrogen source and a high temperature effusion cell for Sc on commercial GaN/sapphire templates with a dislocation density of about 5×10⁸ cm⁻². In this case, a growth temperature of 200° C. and V/III ratio of 1.2 were used, but growth conditions may be used, including, for instance, those described above in connection with FIG. 6. The examples were fabricated such that a 100-nm-thick ScAlN layer, and a 120-nm-thick n-GaN contact layer doped by Si, were grown. For the n-GaN contact layer, the carrier concentration was varied from about 7×10¹⁷ cm⁻³ to about 1×10²⁰ cm⁻³ by tuning silicon cell temperature from 1050° C. to 1250° C. and further calibrated by room temperature Hall effect measurements. Ti/Au and Pt/Au circular electrodes with diameters of 3-50 μm were lithographically patterned. A 200-nm-thick SiO₂ layer deposited by PECVD with small dry-etched openings was used to define electrode areas smaller than 10 μm in diameter.

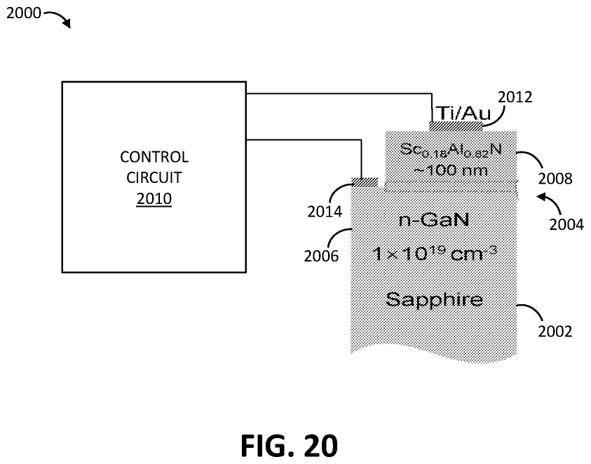

FIG. 20 depicts a memory device 2000 in accordance with one example. The memory device 2000 includes a substrate 2002 and a heterostructure 2004 supported by the substrate 2002, as described herein. Also as described herein, the heterostructure 2004 includes a semiconductor layer 2006 (e.g., a III-nitride semiconductor layer) supported by the substrate 2002, and a ferroelectric III-nitride alloy layer 2008 supported by the semiconductor layer 2006. The ferroelectric III-nitride alloy layer 2008 is composed of, or otherwise includes, a Group IIIB element, such as Sc, and, as described herein, may have a monocrystalline, wurtzite structure.

The memory device 2000 also includes a write/read or other control circuit 2010 in electrical communication with the ferroelectric III-nitride alloy layer 2008 and the semiconductor layer 2006 (e.g., III-nitride semiconductor layer), respectively. The control circuit 2010 may be integrated with the heterostructure 2004 to any desired extent. The control circuit 2010 is configured to apply a poling voltage and a read voltage across the ferroelectric III-nitride alloy layer 2008 and the semiconductor layer 2006 (e.g., III-nitride semiconductor layer), as described herein.

The poling and read voltages may be applied via contacts 2012, 2014 in electrical communication with (e.g., in contact with) the ferroelectric III-nitride alloy layer 2008 and the semiconductor layer 2006 (e.g., III-nitride semiconductor layer), respectively. As a result, a polarity of a poling voltage applied across the contacts 2012, 2014 establishes a state of ferroelectric polarization of the ferroelectric III-nitride alloy layer 2008. In this example, via the application of the poling voltage, the ferroelectric III-nitride alloy layer 2008 resides either in a first polarization state or a second polarization state. The composition, thickness, size, layout, location, and other characteristics of the contacts 2012, 2014 may vary.

The read voltage is at a voltage level to generate a current through the heterostructure, the current having a level indicative of the state of ferroelectric polarization. When the device resides in the first polarization state, current through the heterostructure is at a first (e.g., high or higher) level in response to a read voltage applied across the first and second contacts. In the second polarization state, the current is at a second (e.g., low or lower) level in response to the read voltage. The extent to which the first level is higher than the second level may vary.

As described above, the ferroelectric III-nitride alloy layer may be in contact with the semiconductor layer (e.g., III-nitride semiconductor layer) to establish a heterointerface. In some cases, the ferroelectric III-nitride alloy layer and the semiconductor layer are lattice matched. In other cases, the ferroelectric III-nitride alloy layer and the semiconductor layer are not lattice matched. As described herein, the ferroelectric III-nitride alloy layer may have a scandium content of about 18% to that end, but other compositions may be used (e.g., in connection with other alloys). For instance, the scandium content may fall in a range from about 10% to about 40%. The III-nitride or other semiconductor layer may be doped (e.g., Si doped) to configure the semiconductor layer as an electrode layer. As described herein, the doping may result in a charge carrier concentration that supports the resistive switching of the polarization state of the ferroelectric III-nitride alloy layer.

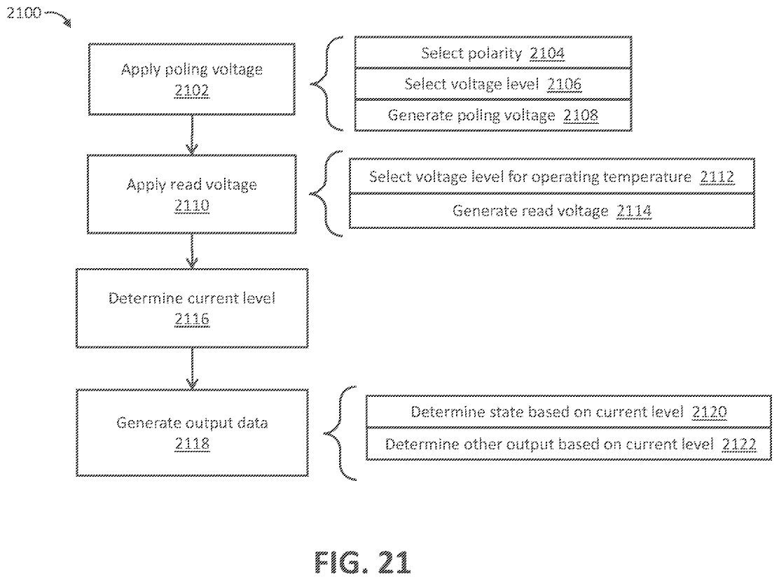

FIG. 21 depicts a method 2100 of operating a memory device in accordance with one example. The method 2100 may be directed to the operation of the memory device of FIG. 20 or another memory device. The method 2100 may be implemented by one or more components of the control circuit shown in FIG. 20 or another control circuit.

The method 2100 may include an act 2102 in which a poling voltage is applied across a heterostructure of the memory device to establish a polarization state of a ferroelectric III-nitride layer of the heterostructure. The ferroelectric III-nitride layer is supported by a III-nitride semiconductor layer of the heterostructure, and is composed of, or otherwise includes, a Group IIIB element, as described herein.

The act 2102 may include selecting a polarity (e.g., positive or negative) for the poling voltage in an act 2104. In an act 2106, a voltage level for the poling voltage may be selected. For instance, the voltage level may be +35 V or −35 V. The level or magnitude of the poling voltage may be selected based on operational conditions (e.g., temperature), characteristics of the heterostructure, and/or other factors. The poling voltage may then be generated in an act 2108 by an amplifier or other voltage source circuit or generator of the control circuit.

In an act 2110, a read voltage is applied across the heterostructure. The act 2110 may include an act 2112 in which a voltage level for the read voltage is selected. The voltage level may be selected based on the operating temperature, one or more characteristics of the heterostructure, and/or other factors. The read voltage may then be generated in an act 2114 by the voltage source circuit or generator.

The selection of the levels of the poling and read voltages may be useful in the absence of cooling devices or procedures. For instance, the device may lack a heat sink or other component directed to cooling. Alternatively or additionally, the device may not be configured to implement a procedure directed to cooling. In these and other cases, the poling and read voltages may nonetheless be applied without such cooling techniques due to (1) the compatibility of the devices with high temperature operation, and (2) the selection of the voltage levels.

The level of the current flowing through the heterostructure in response to the read voltage for readout of the polarization state is then determined in an act 2116. The manner in which the current level is measured or determined may vary. For instance, the control circuit may include any type of current detector or detection circuitry.

In the example of FIG. 21, the method 2100 includes an act 2118 in which output data indicative of the polarization state is generated. The output data may be generated based on, or in accordance with, the current level in an act 2120. One or more other outputs may also be determined based on the current level in an act 2122. For instance, the current level may be indicative of a modulated write voltage as described herein, in which case the information underlying the modulation may be determined and provided as an output.

As described above, the heterostructure may be configured for high temperature operation. Thus, in some cases, one or more of the acts of the method 2100 may be implemented at an operating temperature greater than about 670 K. Other operating conditions (e.g., temperatures) may be present.

Described above are examples of stable epitaxial ScAlN/GaN heterostructure resistive memory devices. An analysis of the coupling between resistive switching and ferroelectric polarization was also provided. The structures exhibited distinct ON and OFF states in response to external bias at room temperature, with a rectifying ratio of about 60 to about 210, retention time of over 3×10⁶ s, and bipolar cycling over 10⁴ times. Polarization-resistance coupled measurements showed the direct correlation between resistive switching and ferroelectric polarization switching. By fitting the I-V curves and tuning the carrier concentration of the GaN semiconductor electrode, conductance modulation was exhibited via electrical polarization engineering at the heterostructure interface. The memory effect exhibited weak dependence on operation temperature, maintaining a maximum rectifying ratio of about 10 even at 670 K. Alternative growth conditions, electrode materials, device structures (e.g., the ferroelectric layer thickness) may be used to fabricate Sc-III-N based memory devices with low operation voltage, high rectifying ratio, long retention time and good endurance resistance comparable to other state-of-the-art memory devices. The examples provided above suggest that ScAlN based ferroelectric/III-nitride heterostructures may be useful for ferroelectric-resistive memory devices, including, for instance, memristors and all nitride-based monolithic integrated logic circuits for power-efficient applications and harsh environments.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate;
a heterostructure supported by the substrate, the heterostructure comprising:
a semiconductor layer supported by the substrate; and
a ferroelectric III-nitride alloy layer supported by the semiconductor layer, the ferroelectric III-nitride alloy layer comprising a Group IIIB element; and
first and second contacts in electrical communication with the ferroelectric III-nitride alloy layer and the semiconductor layer, respectively, such that a polarity of a poling voltage applied across the first and second contacts establishes a state of ferroelectric polarization of the ferroelectric III-nitride alloy layer.

2. The device of claim 1, wherein:
the ferroelectric III-nitride alloy layer resides either in a first polarization state or a second polarization state;
in the first polarization state, current through the heterostructure is at a first level in response to a read voltage applied across the first and second contacts;
in the second polarization state, the current is at a second level in response to the read voltage; and
the first level is higher than the second level.

3. The device of claim 1, wherein the ferroelectric III-nitride alloy layer is in contact with the semiconductor layer to establish a heterointerface.

4. The device of claim 1, wherein the ferroelectric III-nitride alloy layer and the semiconductor layer are lattice matched.

5. The device of claim 1, wherein the ferroelectric III-nitride alloy layer is monocrystalline.

6. The device of claim 1, wherein the ferroelectric III-nitride alloy layer has a wurtzite structure.

7. The device of claim 1, wherein the semiconductor layer is doped to configure the semiconductor layer as an electrode layer having a charge carrier concentration to support resistive switching of a polarization state of the ferroelectric III-nitride alloy layer.

8. The device of claim 1, wherein the semiconductor layer comprises Si-doped GaN.

9. The device of claim 1, wherein the semiconductor layer is in contact with the substrate.

10. The device of claim 1, wherein the ferroelectric III-nitride alloy layer comprises ScAlN.

11. The device of claim 10, wherein the ferroelectric III-nitride alloy layer has a scandium content of about 18%.

12. A device comprising:
a substrate; and
a heterostructure supported by the substrate;
wherein the heterostructure comprises:
a semiconductor layer supported by the substrate; and
a ferroelectric III-nitride alloy layer supported by the semiconductor layer, the ferroelectric III-nitride alloy layer comprising a Group IIIB element, and
wherein the semiconductor layer is doped to configure the semiconductor layer as an electrode layer having a charge carrier concentration to support resistive switching of a polarization state of the ferroelectric III-nitride alloy layer.

13. A memory device comprising:
a substrate;
a heterostructure supported by the substrate, the heterostructure comprising:
a semiconductor layer supported by the substrate; and
a ferroelectric III-nitride alloy layer supported by the semiconductor layer, the ferroelectric III-nitride alloy layer comprising a Group IIIB element, and
a control circuit in electrical communication with the ferroelectric III-nitride alloy layer and the semiconductor layer, respectively, to apply a poling voltage and a read voltage across the ferroelectric III-nitride alloy layer and the semiconductor layer;
wherein:
a polarity of the poling voltage establishes a state of ferroelectric polarization of the ferroelectric III-nitride alloy layer, respectively; and
the read voltage is at a voltage level to generate a current through the heterostructure, the current having a level indicative of the state of ferroelectric polarization.

14. The memory device of claim 13, wherein the ferroelectric III-nitride alloy layer is in contact with the semiconductor layer to establish a heterointerface.

15. The memory device of claim 13, wherein the ferroelectric III-nitride alloy layer and the semiconductor layer are lattice matched.

16. The memory device of claim 13, wherein the ferroelectric III-nitride alloy layer is a monocrystalline wurtzite structure.

17. The memory device of claim 13, wherein the semiconductor layer is Si-doped.

18. The memory device of claim 13, wherein the ferroelectric III-nitride alloy layer comprises ScAlN.

19. A method of operating a memory device, the method comprising:
applying a poling voltage across a heterostructure of the memory device to establish a polarization state of a ferroelectric III-nitride layer of the heterostructure, the ferroelectric III-nitride layer being supported by a semiconductor layer of the heterostructure, the ferroelectric III-nitride alloy layer comprising a Group IIIB element;
applying a read voltage across the heterostructure; and
determining a level of current flowing through the heterostructure in response to the read voltage for readout of the polarization state.

20. The method of claim 19, wherein applying the poling voltage comprises selecting a level of the poling voltage to modulate a conductance of the polarization state.

21. The method of claim 19, wherein:
applying the poling voltage comprises selecting a level of the poling voltage based on an operating temperature; and
applying the read voltage comprises selecting a level of the read voltage based on the operating temperature.

22. The method of claim 21, wherein applying the read voltage is implemented without implementation of a cooling procedure.
